(19) United States
(12) Patent Application Publication
(10) Pub. No.: US 2010/0248609 A1
(43) Pub. Date: Sep. 30, 2010

(54) Assembly For Providing A Downflow Return Air Supply

(75) Inventors: Michael Tresh, Haverhill, MA (US); Brian Jackson, Waltham, MA (US); Edward Bednarcik, East Greenwhich, RI (US); John Prunier, Spencer, MA (US); Martin Olsen, East Greenwich, RI (US); Mark Germagian, North Hubbardston, MA (US); David Lucia, Stafford Springs, CT (US)

Correspondence Address: MIRICK, O'CONNELL, DEMALLIE & LOUGEE, LLP, 1700 WEST PARK DRIVE, WESTBOROUGH, MA, 01581, US

(73) Assignee: Wright Line, LLC, Worcester, MA (US)

(21) Appl. No.: 12/551,657

(22) Filed: Sep. 1, 2009

Related U.S. Application Data
(63) Continuation-in-part of application No. 12/409,647, filed on Mar. 24, 2009.
Application No. 12/409,647 is a continuation-in-part of application No. 12/432,154, filed on Apr. 29, 2009.

(51) Int. Cl. H05K 5/02; F24D 19/00; F28D 15/00; F28F 13/12

(52) U.S. Cl. 454/184; 165/53; 165/104.34; 165/109.1

(57) ABSTRACT

An assembly for supplying heated air to a housing with an interior that is adapted to hold air conditioning equipment. The housing has a top portion and a back portion, where the top portion defines a first opening that leads to the interior of the housing, and where the first opening is proximate the back of the top portion of the housing. The back portion of the housing defines a second opening that leads to the housing interior, where the second opening is proximate the top of the back portion. The assembly includes a flue external to the housing and adapted to be coupled to the housing such that the flue encompasses and is in fluid communication with the first and second openings, the flue defining an inlet for conducting heated air into the flue and an outlet for conducting heated air out of the flue and into the housing through the first and second openings. The air cooled by the air conditioning equipment in the housing is used to cool electronic equipment.

### CROSS-REFERENCE TO RELATED APPLICATIONS

This application is a continuation-in-part of, and claims priority from, co-pending U.S. patent application Ser. No. 12/409,647, entitled “Assembly for Extracting Heat from a Housing for Electronic Equipment,” filed Mar. 24, 2009, and U.S. patent application Ser. No. 12/432,154, filed Apr. 29, 2009, entitled “Systems and Methods for Closed Loop Heat Containment with Cold Aisle Isolation for Data Center Cooling.” The entire contents of both applications are expressly incorporated herein.

### FIELD OF THE INVENTION

This invention relates to an assembly for adapting in-row air conditioning units, such as those used in a data center, to draw heated air from a plenum or duct and provide cooled air to electronic equipment.

### BACKGROUND OF THE INVENTION

Electronic equipment is often located within a housing, such as an equipment rack used to hold computer servers and the like in assemblies that are located within the rack. The electronic equipment generates substantial heat that must be dissipated. Cool air typically passes through the housings to help dissipate heat. In many cases, fans located in the front door and/or back door and/or within the rack and/or in the top of the rack are used to circulate the cold air and expel the warmed air.

One solution proposes a front or back rack panel that is several inches thick, and carries ducting and fans to route air through the rack. Cool air enters the bottom of the front, and exits the top of the back. However, such thickened panels increase the depth of the racks, which inherently limits the number of racks that can be fit into a data center.

As with individual equipment racks, there are heat dissipation and energy consumption issues associate with data centers. Resource demands and constraints, including those related to power, represent a critical concern in the United States today. The increasing demand, and strain, placed upon electrical grids across the United States by data centers of all sizes is a material contributor to this issue.

The United States Environmental Protection Agency (EPA) addressed this issue in August 2007 and submitted a report to the United States Congress as part of public law to help define a vision for achieving energy efficiencies in data centers. The EPA predicts that by 2011, 2% of the United State's entire energy supply will be consumed by data centers.

Currently, data center managers are focused on the delivery of service and dependability. There has been little incentive, however, for data center managers to optimize the energy efficiency of their data center. In addition, the industry has not set any proper benchmarks for attainable energy efficiency targets, which further complicates the situation. Data center managers are primarily concerned about capital costs related to their data center's capacity and reliability. In most cases the energy costs are either hidden among other operating costs or simply absorbed as a cost of doing business. A study by the company IDC Global shows that for every $1.00 US of new server spend in 2005, $0.48 US was spent on power and cooling. This is a sharp increase from the year 2000, when the ratio was $0.21 US per $1.00 US of server spend. This ratio is anticipated to increase even further. It is expected, then, that the immediate demand to create more efficient data centers will be at the forefront of most company's cost saving initiatives.

Prior art legacy data centers typically have the following characteristics:

(1) An open air system that delivers cold air at approximately 55 degrees Fahrenheit (approximately 13 degrees Celsius) via overhead ducting, flooded room supply air, or a raised floor plenum;

(2) Perforated tiles (in a raised floor environment) that are used to channel the cold air from beneath the raised floor plenum into the data center;

(3) Computer racks, server enclosures and free-standing equipment orientated 180 degrees from alternate rows to create hot and cold aisles, which is an accepted best practice. Historically, however, information technology (IT) architecture has been the driving force in deciding the location of the racks and other equipment, leading to a disorganized and inefficient approach to air distribution;

(4) A minimum separation of 4 feet (approximately 1.22 meters) between cold aisles and 3 feet (approximately 0.91 meters) between hot aisles, based on recommendations from the American National Standards Institute (ANSI/TIA/EIA—942 April 2005), National Fire Protection Association (NFPA), National Electric Code (NEC), and local Authority Having Jurisdiction (AHJ);

(5) Dedicated precision air conditioning units located at the nearest perimeter wall and generally in close proximity to IT racks. However, optimal placement of the computer room air conditioner (CRAC) for free air movement is biased by structural columns, and often requires service clearances or other infrastructure accommodations;

(6) Traditional air conditioning systems are “turned on” on day one, and remain at full capability for cooling, even if only a small percentage of the design load is required; and

(7) Existing air conditioning systems have limitations and are sensitive to the location of heat loads in and around the data center, and therefore are not resilient to changing configurations and requirements.

In practice, the airflow in the legacy data center is very unpredictable, and has numerous inefficiencies, which are proliferated as power densities increase. Problems encountered in a data center include: bypass airflow, recirculation, hot and cold air remixing, air stratification, air stagnation, and uncomfortable data center ambient room temperature.

### Bypass Airflow

Bypass airflow is defined as conditioned air that does not reach computer equipment. The most common form of bypass airflow occurs when air supplied from the precision air conditioning units is returned directly back to the air conditioner's intake. Examples of this form of bypass airflow may include leakage areas such as air penetrating through cable cut-outs, holes under cabinets, or misplaced perforated tiles that blow air directly back to the air conditioner's intake. Other examples of bypass airflow include air that escapes through holes in the computer room perimeter walls and non-sealed doors.

A recent study completed by engineers from UpSite Technologies, Inc.™ and Uptime Institute, Inc.® concluded that in conventional legacy data centers only 40% of the air delivered from precision air conditioning units makes its way to cool the existing information technology (IT) equipment. This amounts to a tremendous waste in energy, as well as an excessive and unnecessary operational expense.

### Recirculation

Recirculation occurs when the hot air exhausted from a computing device, typically mounted in a rack or cabinet, is fed back into its own intake or the intake of a different computing device. Recirculation principally occurs in servers located at the highest points of a high-density rack enclosure. Recirculation can result in potential overheating and damage to computing equipment, which may cause disruption to mission-critical services in the data center.

### Hot and Cold Air Remixing and Air Stratification

Air stratification in a data center is defined as the layering effect of temperature gradients from the bottom to the top of the rack or cabinet enclosure.

In general, in a raised floor environment, air is delivered at approximately 55 degrees Fahrenheit (approximately 13 degrees Celsius) from under the raised floor through perforated tiles. The temperature of the air as it penetrates the perforated tile remains the same as the supply temperature. As the air moves vertically up the rack however, the air temperatures gradually increase. In high-density rack enclosures it is not uncommon for temperatures to exceed 90 degrees Fahrenheit (approximately 32 degrees Celsius) at the server intakes mounted at the highest point of the rack enclosure. The recommended temperature range however, for server intakes, as stated by ASHRAE Technical Committee 9.9 Mission Critical Facilities, is between 68 and 77 degrees Fahrenheit (approximately 20 to 25 degrees Celsius).

Thus, in a legacy data center design, the computer room is overcooled by sending extremely cold air under the raised floor, simply because there is a lack of temperature control as the air moves upward through the rack or cabinet enclosure.

In addition, because the hot air and the cold air are not isolated, and tend to mix, dedicated air conditioning units are typically located close to the rack enclosures, which may not be the most efficient or economical placement. In some situations, the most efficient or economical solution may be to use the building's air conditioning system, rather than having air conditioning units that are dedicated to the data center, or a combination of dedicated air conditioning units and the building's air conditioning system.

### Air Stagnation

Large data centers typically have areas where the air does not flow naturally. As a result, the available cooling cannot be delivered to the computing equipment. In practice, data centers may take measures to generate air flow in these areas by utilizing air scoops, directional vanes, oscillating floor fans, and active fan-based floor tiles.

### Uncomfortable Data Center Ambient Room Temperature

Data center ambient room temperature is not conditioned to comfortable working conditions. The ambient air temperature in a data center is typically determined by inefficiencies between providing cool air and removing heated air.

To address some of these concerns, data centers may be equipped with in-row air conditioning units, either in place of, or to supplement, larger computer-room air conditioners. These in-row cooling units extract hot air from the room or the hot aisle and return cooled air to the cold aisle. A particular in-row air conditioning unit, however, is constrained by its location, in that it may only be used to cool the equipment in the row in which it is located. An in-row air conditioning unit's excess cooling capacity cannot be used to cool equipment racks in a different row. In addition, an in-row air conditioning unit does nothing to reduce the temperature in the hot aisle, and in some cases, may actually increase the temperature in the hot aisle beyond recommended safety limits.

There is a need in the art, then, for improved methods for heat dissipation in equipment racks, and improved systems and methods for heat containment and cold air isolation in data centers. In particular, there is a need to remedy the typical problems encountered in a data center, including bypass airflow, recirculation, hot and cold air remixing, air stagnation, air stratification, and uncomfortable data center ambient room temperature. Improved systems and method are needed to eliminate wasted conditioned air and increase air conditioner efficiency. In addition, there is a need in the art for assemblies and systems for retrofitting existing data centers, equipment racks and in-row air-conditioning units, to provide the benefits of improved heat dissipation and air flow without wholesale replacement of equipment.

### SUMMARY OF THE INVENTION

It is therefore an object of this invention to provide an assembly for adapting in-row air conditioning units, such as those used in a data center, to draw heated air from a plenum or duct and provide cooled air to electronic equipment housings.

In an embodiment, the invention provides an assembly for supplying heated air to a housing with an interior that is adapted to hold air conditioning equipment, where the housing comprises a top portion and a back portion, where the top portion defines a first opening that leads to the housing interior, the first opening located proximate the back of the top portion, where the back portion defines a second opening that leads to the housing interior, the second opening located proximate the top of the back portion, and where the first opening is contiguous with the second opening, and the assembly comprises a flue external to the housing and adapted to be coupled to the housing such that the flue encompasses and is fluid communication with the first and second openings, where the flue defines an inlet for conducting air into the flue and an outlet for conducting air out of the flue and into the housing through the first and second openings.

In an aspect, the housing further comprises a support assembly that supports the housing's top and back portions, and the assembly for supplying heated air further comprises an intermediate assembly adapted to be coupled to the support assembly, where the intermediate assembly defines at least part of the back portion of the housing, and where the flue is coupled to the intermediate assembly.

In another aspect, the intermediate assembly comprises an intermediate assembly frame member defining at least two sides of the back portion of the housing.

In an aspect, the intermediate assembly further comprises a door assembly hingedly coupled to the intermediate assembly frame member, to allow user access to the interior of the housing. In another aspect, the door assembly comprises two doors, one hinged to each side of the intermediate assembly frame member. In yet another aspect, the door assembly and the intermediate assembly frame member together define the back portion of the housing. In an additional aspect, the intermediate assembly defines the entire back portion and at least some of the top portion of the housing.

In an aspect, the flue comprises a first section that is coupled to the intermediate assembly, and the first section extends out from the back portion of the housing at an angle of less than 90 degrees. In another aspect, the back portion of the housing is essentially vertical and the top portion of the housing is essentially horizontal such that the top portion and the back portion are essentially perpendicular and meet to define the top back corner of the housing, and wherein the first section of the flue comprises essentially perpendicular members that define a coupling portion such that when the flue is coupled to the housing the coupling portion fits tightly over the top back corner of the housing.

In an aspect, the flue further comprises a second section that extends essentially vertically from the first section. In another aspect, the second section of the flue is an essentially rectangular duct.

In an aspect, one or more fan trays are located within the flue. In another aspect, the fan trays are hot-swappable. In yet another aspect, the second section of the flue defines a hinged access door to allow access to the fan trays.

In another embodiment, the invention provides an assembly for supplying heated air to a housing with an interior that is adapted to hold air conditioning equipment, the housing comprising a top portion and a back portion, where the top portion defines a first opening that leads to the housing interior, the first opening located proximate the back of the top portion, where the back portion defines a second opening that leads to the housing interior, the second opening located proximate the top of the back portion, and where the first opening is contiguous with the second opening, the assembly comprising: a) an intermediate assembly adapted to be coupled to the support assembly, the intermediate assembly defining at least part of the back portion of the housing and at least part of the top portion of the housing, the intermediate assembly further defining: i) a first opening extending across substantially all of the width of the top portion of the housing and leading to the housing interior, the first opening located at the back of the top portion, proximate the back portion of the housing; and ii) a second opening extending across substantially all of the width of the back portion of the housing and leading to the housing interior, the second opening located at the top of the back portion, proximate the top portion of the housing; and b) a flue external to the housing and adapted to be coupled to the intermediate assembly below the second opening and in front of the first opening such that the flue encompasses and is in fluid communication with the first and second openings, the flue defining an inlet for conducting air into the flue and an outlet for conducting air out of the flue and into the housing through the first and second openings.

In an aspect, the flue comprises essentially perpendicular members that define a coupling portion, such that when the flue is coupled to the housing the coupling portion fits tightly over and follows the contour of the top back corner of the housing.

In an additional embodiment, the invention provides an assembly for supplying heated air to a housing with an interior that is adapted to hold air conditioning equipment, the housing comprising a top portion and a back portion, where the top portion defines a first opening that leads to the housing interior, the first opening located proximate the back of the top portion, where the back portion defines a second opening that leads to the housing interior, the second opening located proximate the top of the back portion, and where the first opening is contiguous with the second opening, the assembly comprising: a) an intermediate assembly adapted to be coupled to the support assembly, the intermediate assembly defining at least part of the back portion of the housing and at least part of the top portion of the housing, the intermediate assembly further defining: i) a first opening extending across substantially all of the width of the top portion of the housing and leading to the housing interior, the first opening located at the back of the top portion, proximate the back portion of the housing; and ii) a second opening extending across substantially all of the width of the back portion of the housing and leading to the housing interior, the second opening located at the top of the back portion, proximate the top portion of the housing; and b) a flue external to the housing and adapted to be coupled to the intermediate assembly below the second opening and in front of the first opening, where the flue defines an air passageway encompasses and is in fluid communication with the first and second openings, the air passageway defining an inlet for conducting air into the air passageway and an outlet for conducting air out of the passageway and into the housing through the first and second openings.

In an aspect, the flue comprises essentially perpendicular members that define a coupling portion, such that when the flue is coupled to the housing the coupling portion fits tightly over and follows the contour of the top back corner of the housing. In another aspect, the flue extends out an angle of no more than about ninety degrees from the back portion of the housing. In an additional aspect, the flue extends out from the back portion of the housing, and the flue extends up after extending out from the back portion of the housing.

In yet another embodiment, the invention provides a system for use in a data center, the system comprising: a plurality of cabinets, each cabinet comprising a generally rectangular vertical front face, two generally rectangular vertical side faces coupled to the front face, a generally rectangular top face coupled to the side faces and to the front face, a generally rectangular back face coupled to the side faces, wherein the plurality of cabinets are arranged in a first row and a second row horizontally displaced from each other such that the front faces of the cabinets in the first row are facing the front faces of the cabinets in the second row to define a cold aisle between the front faces; where at least one of the cabinets is an equipment cabinet adapted to house one or more heat-generating components, and at least one of the cabinets is an air-conditioning cabinet adapted to house one or more air-cooling components; a first baffle proximate the front face of a first cabinet in the first row and the front face of a first cabinet in the second row, the first baffle being configured to inhibit horizontal airflow into and out of the cold aisle; a second baffle proximate the front face of a last cabinet in the first row and the front face of a last cabinet in the second row, the second baffle being configured to inhibit horizontal airflow into and out of the cold aisle; a chimney in communication with the equipment cabinet, for conducting air warmed by the heat-generating components from the interior of the equipment cabinet to a location above the cabinets; and a flue in communication with the air-conditioning cabinet, for conducting warmed air from a location above the cabinets to the interior of the air-conditioning cabinet.

In an aspect the chimney defines an air passageway that is in fluid communication with the interior of the equipment cabinet, the air passageway comprising an inlet for taking in air leaving the equipment cabinet and an outlet for conducting the air out of the air passageway to the location above the cabinets. In another aspect, the flue defines an air passageway that is in fluid communication with the interior of the air-conditioning cabinet, the air passageway comprising an inlet for conducting air from the location above the cabinets into the air passageway and an outlet for conducting air out of the air passageway into the air-conditioning cabinet.

It is a further object of this invention to provide a rack cooling system that maintains the depth of the rack to a minimum, thus maximizing data center rack capacity.

This invention features an assembly for extracting heat from a housing for electronic equipment, the housing having a front, a back, two sides and a top, the assembly comprising a back for the housing that defines an open area proximate the top, and an air passageway in fluid communication with the open area in the back, to conduct heated air exiting the housing through the open area away from the housing. The open area preferably extends across at least the majority of the width of the back, and may extend across substantially all of the width of the back. The open area may also encompass a portion of the top adjacent to the back. The open area could alternatively be located in the top proximate the back. The front of the housing may be perforated. The housing may comprise an electronic equipment rack.

The assembly may further comprise an air-moving device in fluid communication with the air passageway. The air-moving device may be located in the air passageway, or located at the intersection of the back of the housing and the air passageway.

The air passageway may be directly coupled to the back of the housing. The air passageway may extend out from the back of the housing. The air passageway may further extend up after extending out from the back of the housing. In one particular embodiment, the air passageway may extend out at an angle of no more than about ninety degrees from the back of the housing; in a more particular embodiment, the air passageway may extend out at an angle of about forty-five degrees.

The air passageway may comprise a duct. The duct may be flexible or not. The assembly may comprise at least two ducts which are essentially parallel to one another. The assembly may further comprise an air-moving device in each duct. The air passageway may be located a sufficient height off the floor so as to meet relevant height safety regulations. There may be essentially no openings in the housing top, so that the entire top area is available for routing of additional equipment.

The invention also features an assembly for extracting heat from a housing with an interior that is adapted to hold heat-generating electronic equipment, the housing comprising a top portion and a back portion, and defining a first opening in the top portion of the housing that leads to the housing interior, the first opening located at the back of the top portion, proximate the back portion of the housing, and structure defining a second opening in the back portion of the housing that leads to the housing interior, the second opening located at the top of the back portion, proximate the top portion of the housing. A chimney external to the housing is adapted to be coupled to the housing such that the chimney encompasses and is in fluid communication with the first and second openings, the chimney defining an inlet for taking in air leaving the housing through the first and second openings and an outlet for conducting the air out of the chimney.

The chimney may be coupled to the back portion of the housing below the second opening, and coupled to the top portion of the housing in front of the first opening. The back portion of the housing may be essentially vertical, and the chimney may extend out from the back portion of the housing. The chimney may extend up after extending out from the back portion of the housing. The chimney may extend out at an angle of less than ninety degrees from the back portion of the housing; the angle may be about forty-five degrees.

The first opening may extend across at least a majority of the width of the top portion of the housing, or across substantially all of the width of the top portion of the housing. The second opening may extend across at least a majority of the width of the back portion of the housing, or across substantially all of the width of the back portion of the housing. The assembly may further comprise at least one air-moving device in fluid communication with the chimney, which may be located in the chimney. The back portion of the housing may comprise one or more doors, to provide access to the housing through the back.

The housing may further comprise a support assembly that supports the housing's top and back portions, and the assembly for extracting heat may further comprise an intermediate assembly coupled to the support assembly, the intermediate assembly defining at least part of the back portion of the housing, wherein the chimney is coupled to the intermediate assembly. The intermediate assembly may comprise an intermediate assembly frame member defining two sides and the bottom of the back portion of the housing. The intermediate assembly may further comprise a door assembly hingedly coupled to the intermediate assembly frame member, to allow user access to the interior of the housing. The door assembly may comprise two doors, one hinged to each side of the intermediate assembly frame member. The doors and the intermediate assembly frame member may together define the back portion of the housing. The intermediate assembly may define the entire back portion and at least some of the top portion of the housing.

The chimney may comprise a first section that is coupled to the intermediate assembly, the first section extending out from the back portion of the housing at an angle of less than 90 degrees. The chimney may further comprise a second section that extends essentially vertically from the first section. The second section of the chimney may be an essentially rectangular duct. The assembly may further comprise one or more fan trays located within the chimney. The fan trays may be hot-swappable. The second section of the chimney may define an access door to allow access to the fan trays.

Also featured is an assembly for extracting heat from a housing with an interior that is adapted to hold heat-generating electronic equipment, the housing comprising an essentially solid top portion, an essentially solid back portion, and a support assembly that supports the housing's top and back portions, the assembly for extracting heat comprising a first opening extending across substantially all of the width of the top portion of the housing and leading to the housing interior, the first opening located at the back of the top portion, proximate the back portion of the housing, a second opening extending across substantially all of the width of the back portion of the housing and leading to the housing interior, the second opening located at the top of the back portion, proximate the top portion of the housing, an intermediate assembly coupled to the support assembly, the intermediate assembly defining at least part of the back portion of the housing and at least part of the top portion of the housing, and a chimney external to the housing and coupled to the intermediate assembly below the second opening and in front of the first opening such that the chimney encompasses and is in fluid communication with the first and second openings, the chimney defining an inlet for taking in air leaving the housing through the first and second openings and an outlet for conducting the air out of the chimney.

The invention also features a data center arrangement comprising at least two electronic equipment racks, each rack having a front, a back, two sides and a top, the arrangement comprising two electronic equipment racks spaced apart by about thirty-six inches, the back of each rack being essentially solid except for an open area proximate the top, and at least one air passageway in fluid communication with the open area in the back of each rack, to conduct heated air exiting the rack through the open area away from the rack. The data center may further comprise an enclosed ceiling. The air passageways may be in fluid communication with the enclosed ceiling. The data center may further comprise an air-cooling apparatus in fluid communication with the enclosed ceiling. The data center may further comprise means for providing cooled air from the air-cooling apparatus to the front of the racks.

The invention also provides improved systems and methods for heat containment and cold air isolation in data centers. The combination of elements in the invention, including the use of chimneys, ducts, plenums, baffles, and fans, provides a unique and effective solution to the typical problems encountered in a data center, including bypass airflow, recirculation, hot and cold air remixing and air stratification, air stagnation, and uncomfortable data center ambient room temperature. The invention also reduces or eliminates wasted conditioned air and increases air conditioner efficiency. Advantages of the invention include:

(1) Preventing the mixing of the hot air and cold air in a data center through ducting, plenums, and physical separation;

(2) Returning higher temperature air directly to the air conditioner to allow the air conditioner to operate more efficiently, as well as allowing the same cooling device to remove more heat, as typically measured in BTUs (British Thermal Units) per unit, thus increasing the cooling capacity of the air conditioner;

(3) Providing an opportunity to use dedicated data center air conditioning units, the building air conditioning system, or a combination of both to make the most efficient use of the air conditioning equipment;

(4) Providing an opportunity to run the data center (outside of the isolated cold isle) at near standard office temperatures, thus reducing significantly the amount of cold air that needs to be generated and treated and the energy required to power the air conditioners, and providing a more comfortable working environment;

(5) Allowing for both scalability of solution as well as integration into many different types of data center rooms and environments varying in both size as well as density of equipment;

(6) Allowing the data center to use air-side economizers to exchange heated air with cooler outside air through the aggregation of the hot air to a plenum, thus reducing the cooling system power consumption; and

(7) Permitting non-standard floor rack layouts, where the cabinets and enclosures are not arranged in a hot/cold aisle arrangement, which is often required to support the IT function or network demands, thus increasing performance by containing the hot and cool air

The invention combines server cabinets or enclosures with a number of elements, including chimneys that attach to the top, rear, or top and rear of the cabinets or enclosures to facilitate the removal of the hot air; top and air seal kits; solid rear and/or front doors or panels on the enclosures; perforated front doors or panels on the enclosures; and special divider baffles, such as doors and panels, for heat containment and cold air isolation. The chimneys, ducts and/or plenums may also include fans and/or baffles, which may also be redundant. Ducts attached to the tops of the chimneys return hot air from the cabinets or enclosures to one of the following:

(1) A below-ceiling duct that returns the hot air to a computer room air conditioner and/or the building's air conditioning system;

(2) A vertical duct that exhausts air high into a room, such that a computer room air conditioner and/or building air conditioning system will intake that exhausted hot air.

(3) A pressurized ceiling plenum or suspended ceiling that returns the hot air to a computer room air conditioner and/or the building's air conditioning system;

The invention may also include air conditioning units to supply cool air to the cabinets. The air conditioning units may be redundant. In other embodiments the building's air conditioning system may be used instead of, or in combination with, dedicated data center precision air conditioning units. In addition, the ducts to and from the air conditioning units may be configured to allow any one air conditioning unit to selectively service one or more rows of cabinets through the use of baffles and/or fans. The baffles and/or fans may also be used to control the air pressure within the chimneys, ducts, and/or plenums. The invention thus effectively contains the hot air exhausted by the computer equipment and IT hardware located in the cabinets or enclosures. In addition, by adding baffles, such as doors or panels, that join the rows of enclosures on each end, and face each other across a row (typically called the cold aisle), and by optionally attaching a roof or cover comprised typically of clear material such as, but not exclusively, Plexiglas®, the invention isolates the cold air that is piped from the air conditioning units typically under floor, in-row, or overhead, into the cold aisle. The invention thus combines elements to provide both heat containment and cold air isolation.

The invention further contemplates instrumenting various locations and equipment in the data center to monitor and control temperature, air pressure, power consumption, efficiency, and overall availability.

In preferred embodiments, the invention provides a system for use in a data center having a source of cool air, the system comprising a plurality of cabinets, each cabinet comprising a generally rectangular vertical front face, two generally rectangular vertical side faces coupled to the front face, a generally rectangular top face coupled to the side faces and to the front face, a generally rectangular back face coupled to the side faces, and an interior that is adapted to house one or more heat-generating components, each of the cabinets adapted to intake the cool air, wherein the plurality of cabinets are arranged in a first row and a second row horizontally displaced from each other such that the front faces of the cabinets in the first row are facing the front faces of the cabinets in the second row to define a cold aisle between the front faces; a first baffle proximate the front face of a first cabinet in the first row and the front face of a first cabinet in the second row, the first baffle being configured to inhibit horizontal airflow into and out of the cold aisle; a second baffle proximate the front face of a last cabinet in the first row and the front face of a last cabinet in the second row, the second baffle being configured to inhibit horizontal airflow into and out of the cold aisle; and at least one chimney in communication with at least one cabinet, for conducting air warmed by the heat-generating components to a location above the cabinets.

In an aspect, the chimney defines an air passageway that is in fluid communication with the interior of the cabinet, the air passageway comprising an inlet for taking in air leaving the cabinet and an outlet for conducting the air out of the air passageway to the location above the cabinets.

In another aspect, the top face of each cabinet defines a first opening leading to the rack interior, with the first opening located at the back of the top face, proximate the back face; the back face of each cabinet defines a second opening leading to the cabinet interior, with the second opening located at the top of the back face, proximate the top face; the first opening is contiguous with the second opening; and the chimney defines an air passageway that encompasses and is in fluid communication with the first and second openings, with the air passageway comprising an inlet for taking in air leaving the cabinet, and an outlet for conducting the air out of the air passageway to the location above the cabinets.

In an aspect, the chimney includes a fan. In another aspect, the chimney is in communication with the top face of the cabinet. In a further aspect, the chimney is in communication with the rear face of the cabinet. In yet another aspect, the chimney is in communication with the top and rear faces of the cabinet.

In an aspect, one or more air conditioning units are configured to source the cool air to the data center. In another aspect, the cool air is delivered to the cold aisle through a plurality of perforations in a floor of the data center. In a further aspect, the cool air is delivered to the cold aisle through the bottoms of the cabinets. In another aspect, the cool air is delivered directly into the cold aisle through one or more ducts. In yet another aspect, at least one duct is in communication with the chimney, to conduct air warmed by the heat-generating components to a suspended ceiling.

In an aspect, the duct comprises a fan or baffle. In another aspect, at least one duct is in communication with the chimney, to conduct air warmed by the heat-generating components directly to an intake of at least one of the air conditioning units. In a further aspect, at least one of the first baffle or the second baffle comprises a door. In yet a further aspect, at least one of the baffles comprises a window.

In an aspect, a cover joins the first row of cabinets and the second row of cabinets, with the cover being configured to inhibit vertical airflow into and out of the cold aisle. In another aspect, the cover includes a translucent panel.

In an additional preferred embodiment, the invention provides a method of cooling heat-generating components housed in cabinets in a data center, the method comprising providing cool air to a first region between two rows of cabinets, including a first row and a second row that is substantially parallel to the first row, with a front face of at least one of the cabinets in the first row facing towards a front face of at least one of the cabinets in the second row; inhibiting the cool air from exiting the first region through the location between a first cabinet of the first row and a first cabinet of the second row; inhibiting the cool air from exiting the first region through the location between a last cabinet of the first row and a last cabinet of the second row; exhausting warm air from the heat-generating equipment through a chimney in communication with at least one of the cabinets to a second region above the first and second row; and inhibiting the warm air from entering the first region.

These and other aspects of the invention will become apparent from the following description. In the description, reference is made to the accompanying drawings, which form a part hereof, and in which there are shown preferred embodiments of the invention. Such embodiments do not necessarily represent the full scope of the invention, and reference is therefore made to the claims for understanding the true scope of the invention.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1A is a schematic conceptual diagram of the assembly for extracting heat from a housing for electronic equipment of this invention;

FIGS. 1B and 1C are similar drawings of two alternative embodiments of the invention;

FIG. 2 is a schematic, cross-sectional view of another embodiment of the invention accomplished in a computer equipment rack with an assembly for extracting heat from the rack in accordance with the present invention;

FIG. 3 is a similar view showing two adjacent racks in a data center arrangement according to this invention;

FIG. 4 is a perspective representation of a data center utilizing a closed loop heat containment and cold aisle isolation system according to a preferred embodiment of the present invention, in which the warmed air from the cabinets is exhausted into a below-ceiling duct;

FIG. 5 is a top representation of the data center of FIG. 4;

FIG. 6 is a side representation of the data center of FIG. 4;

FIG. 7A is a side view of a first embodiment of a cabinet with a chimney, according to a preferred embodiment of the invention, in which cool air enters the cabinet through a perforated front panel or door, and the chimney is attached to the top and rear of the cabinet;

FIG. 7B is a side view of a second embodiment of a cabinet with a chimney, according to a preferred embodiment of the invention, in which cool air enters the cabinet through a perforated front panel or door, and the chimney is attached to the rear of the cabinet;

FIG. 7C is a side view of a third embodiment of a cabinet with a chimney, according to a preferred embodiment of the invention, in which cool air enters the cabinet through a perforated front panel or door, and the chimney is attached to the top of the cabinet;

FIG. 7D is a side view of a fourth embodiment of a cabinet with a chimney, according to a preferred embodiment of the invention, in which cool air enters the cabinet through the bottom of the cabinet, and the chimney is attached to the top and rear of the cabinet;

FIG. 7E is a side view of a fifth embodiment of a cabinet with a chimney, according to a preferred embodiment of the invention, in which cool air enters the cabinet through the bottom of the cabinet, and the chimney is attached to the rear of the cabinet;

FIG. 7F is a side view of a sixth embodiment of a cabinet with a chimney, according to a preferred embodiment of the invention, in which cool air enters the cabinet through the bottom of the cabinet, and the chimney is attached to the top of the cabinet;

FIG. 8A is a representation of the airflow management within the data center of FIG. 4, where the cool air enters the cabinets through perforated front panels or doors;

FIG. 8B is a representation of the airflow management within the data center of FIG. 4, where the cool air enters the cabinets through the bottoms of the cabinets;

FIG. 9 is a perspective representation of a data center according to alternate embodiment of the invention, in which the warmed air from the cabinets is exhausted at a high elevation within the data center;

FIG. 10 is a side representation of the data center of FIG. 9;

FIG. 11 is a perspective representation of a data center according to an alternate embodiment of the invention, in which the warmed air from the cabinets is exhausted into a pressurized ceiling plenum or suspended ceiling;

FIG. 12 is a side representation of the data center of FIG. 9;

FIG. 13 is a top representation of a data center utilizing a closed loop heat containment and cold aisle isolation system according to a preferred embodiment of the invention, in which each air conditioning unit is configured to selectively service one or more rows of cabinets through the use of baffles and/or fans;

FIG. 14 is a top representation of a data center utilizing a closed loop heat containment and cold aisle system according to a preferred embodiment of the invention, in which the air conditioning units are redundant, and each air conditioning unit is configured to selectively service one or more rows of cabinets through the use of baffles and/or fans;

FIG. 15 is a perspective representation of a data center according to an alternate embodiment of the invention, in which the cabinets are not arranged to form hot aisles and cold aisles, and warmed air from the cabinets is exhausted into a below-ceiling duct;

FIG. 16 is a perspective representation of a data center according to an alternate embodiment of the invention, in which the cabinets are not arranged to form hot aisles and cold aisles, and warmed air from the cabinets is exhausted into a pressurized ceiling plenum or suspended ceiling;

FIG. 17 is a perspective representation of a data center according to an alternate embodiment of the invention, in which the cabinets are not arranged to form hot and cold aisles, but are configured in a “chaos” layout, and warmed air from the cabinets is exhausted into a below-ceiling duct;

FIG. 18 is a perspective representation of a data center according to an alternate embodiment of the invention, in which the cabinets are not arranged to form hot and cold aisles, but are configured in a “chaos” layout, and warmed air from the cabinets is exhausted into a pressurized ceiling plenum or suspended ceiling;

FIG. 19 is a perspective representation of a data center according to an alternate embodiment of the invention, in which the heated air is aggregated, and an air-side economizer is used to cool the heated air with cool outside air;

FIG. 20A is a perspective view of an embodiment of a chimney for the inventive assembly;

FIG. 20B is an exploded view of a chimney that is essentially the same as that shown in FIG. 20A;

FIG. 21A is a perspective view of an intermediate assembly for an embodiment of the inventive assembly;

FIG. 21B shows the intermediate assembly of FIG. 21A with doors that allow access to the interior of the enclosure;

FIG. 22 shows the chimney of FIG. 20A coupled to the intermediate assembly of FIG. 21B;

FIG. 23A is an exploded view of the frame of an enclosure with an embodiment of the inventive assembly;

FIG. 23B is an exploded view of an enclosure with an embodiment of the inventive assembly;

FIG. 24 is a view similar to that of FIG. 21A, but for an alternative intermediate assembly that further comprises a top panel for the enclosure;

FIG. 25 is a perspective representation of a data center utilizing a closed loop heat containment and cold aisle isolation system according to a preferred embodiment of the present invention, in which the warmed air from the cabinets is exhausted into a below-ceiling duct and an in-line air conditioning unit draws warmed air from the below-ceiling duct; and

FIG. 26 is a schematic conceptual diagram of the air flow through an in-line air conditioning unit coupled to an embodiment of the flue or duct of FIG. 20A.

### DETAILED DESCRIPTION OF THE PREFERRED EMBODIMENTS OF THE INVENTION

This invention may be accomplished in an assembly for extracting heat from a housing for electronic equipment, the housing having a front, a back, two sides and a top, the assembly comprising a back for the housing that defines an open area proximate the top, and an air passageway in fluid communication with the open area in the back, to conduct heated air exiting the housing through the open area away from the housing. Typically, the front is perforated and the sides are solid, so that air flows into the housing through the front, through the electronic equipment located in the housing, and out of the housing through the open area, into the passageway.

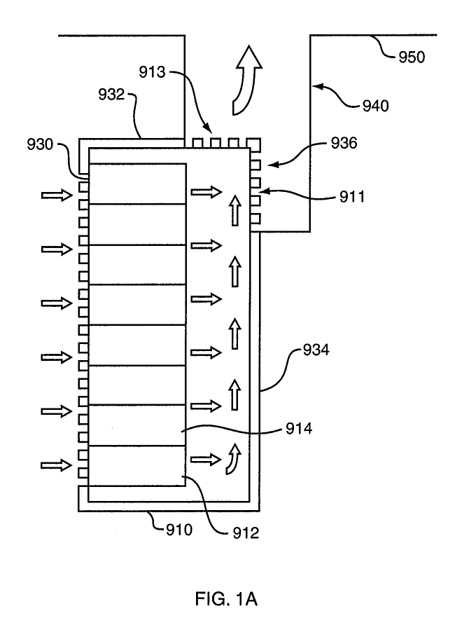

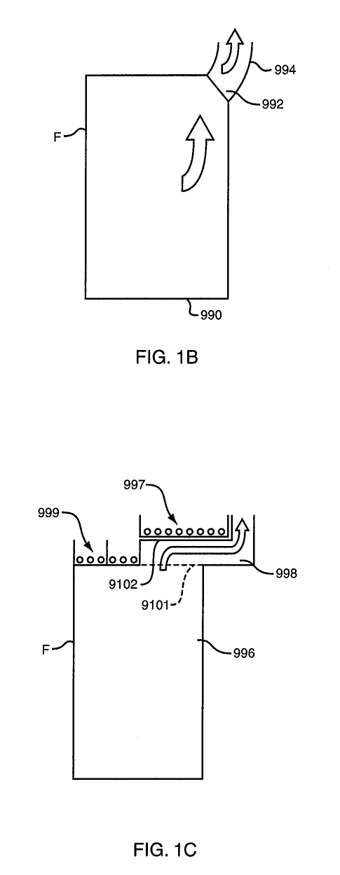

FIGS. 1A-1C schematically depict three concepts for accomplishing the invention, which is an assembly for extracting heat from a housing for electronic equipment. In this case, housing 910 may be a computer server rack such as a “Paramount” enclosure offered by Wright Line LLC of Worcester, Mass. Computer equipment rack 910 holds a number of modules or the like each comprising computer equipment; a series of vertically-arranged computer server modules 912, 914 . . . 920 are shown. Rack 910 is a rectangular prism with front 930, top 932, and back 934. The two solid sides are not shown in the drawing. In accordance with the invention, back 934 is essentially solid except for open area 936 comprising opening or perforated area 911 in back 934 proximate top 932 and opening or perforated area 913 in top 932 proximate back 934. The open area 936 comprises some of the back, and may include an adjacent portion of the top as shown in this drawing. Air passageway 940 is in fluid communication with open area 936, to conduct heated air exiting housing 910 through open area 936 away from housing 910 and into enclosed air return ceiling area 950. Cool air enters housing 910 through perforated front door 930.

FIGS. 1B and 1C are two additional conceptual embodiments of the invention. Embodiment 990, FIG. 1B, has open area 992 at the top/back corner, with air passageway 994 communicating therewith. Air enters through front F. Embodiment 996, FIG. 1C, has open area 9101 in the top, with air passageway 998 communicating therewith. Air enters through front F. In this case, even though the heated air outlet is in the top (and could also be in some of the adjacent back, a feature not shown in this drawing), the top is still available to carry cables and/or other equipment by including raised top portion 9102, which forms part of passageway 998. Top portion 9102 can actually be the top of a rigid version of passageway 998, which may be accomplished with a duct. Cable trays 997 and 999 route cables or other equipment along the top.

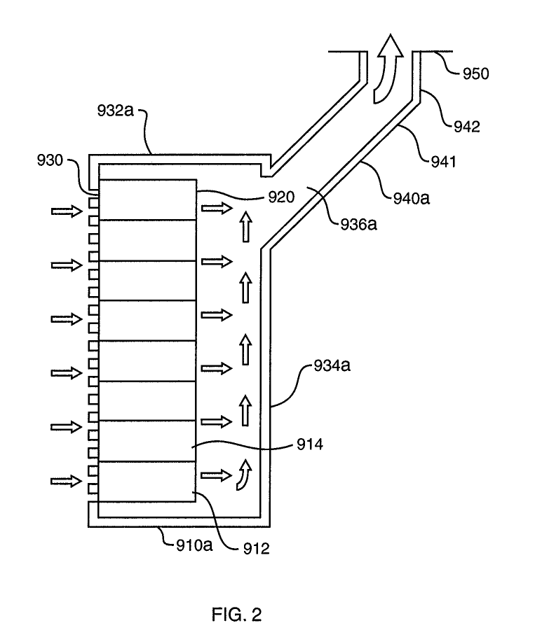

One preferred embodiment of an assembly for extracting heat from a housing for electronic equipment is shown in FIG. 2. Computer equipment rack 910a holds a number of modules or the like each comprising computer equipment; a series of vertically-arranged modules 912, 914 . . . 920 are shown. Rack 910a is typically a rectangular prism shape, and has a perforated front 930, top 932a, and back 934a; the solid side panels are not shown. In accordance with the invention, back 934a is essentially solid except for open area 936a proximate top 932a. Air passageway 940a is in fluid communication with open area 936a, to conduct heated air exiting housing 910a through open area 936a away from housing 910a. Air passageway 940a in this example comprises first section 941 that is angled at about 45 degrees up and away from the plane of back 934a, and more vertical section 942 that leads to enclosed air return ceiling area 950. Cool air enters housing 910a through perforated front door 930.

The invention contemplates any reasonable arrangement of an air passageway that is in fluid communication with an open area at the top of the back and/or the back of the top. The open area preferably extends across at least a majority of the width of the back of the housing, and may also encompass a portion of the top of the housing adjacent to the back, as shown in FIGS. 1A and 1B. In the preferred embodiment, a significant portion of the top is essentially solid so that the majority (or all) of the top area of the housing is available for routing cables and holding other peripheral equipment that is necessary in a data center, as shown in FIG. 1C. This contrasts the invention with racks that have one or more openings in the top that directly vent heated air into the room or a vertical duct but that take away area from the top of the racks that could otherwise be used for routing other data center equipment, such as power and data cables and the like.

The open area can be any shape or arrangement. The assembly of this invention can be installed in a new equipment rack or offered as an after-market product with a back having a particular size, shape and location of an open area, and an air passageway that may be accomplished with one or more flexible or inflexible ducts or conduits, depending upon the particular arrangement.

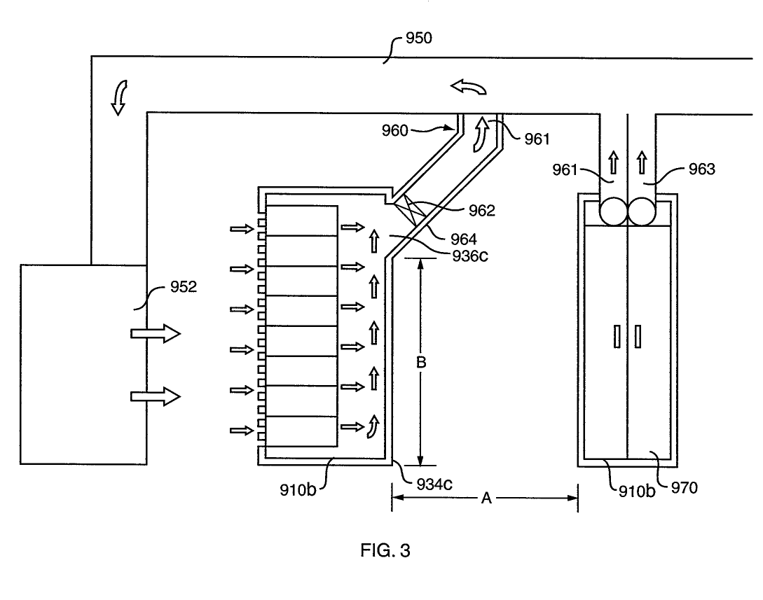

Once such particular arrangement is shown in FIG. 3, which illustrates two adjacent identical racks 910b, one in cross section and one in a rear view. Air passageway 960 comprises two side-by-side essentially identical circular flexible ducts 961 and 963 that are coupled to the upper back area of each of equipment rack 910a (viewed from the side) and rack 910b (viewed from the back, in which split rear door 970, located below ducts 961 and 963, is visible). This drawing also illustrates one option in which an air-moving device 962 is placed in air passageway 960, or in fluid communication therewith, to assist the movement of air.

Overall airflow is depicted in the drawings by the solid arrows. Preferably, the solid front door of the rack is replaced with a perforated front that has a series of openings, somewhat like a screen door. This allows cooled room air to enter the front of the rack and pass through equipment modules 912, 914 . . . 920. Heated air flows out through the back of these modules, typically assisted by fans located in the modules themselves. The heated air is naturally buoyant and rises along back 934c and out through open area 936c. The inventive assembly thus acts somewhat like a chimney in that it is a passageway to allow heated air to escape from the inside of a housing for electronic equipment.

FIG. 3 also illustrates an embodiment of a data center arrangement according to this invention comprising two or more electronic equipment racks 910a and 910b. In this embodiment, racks 910a and 910b are essentially equivalent to rack 910, FIG. 1, except for the particular arrangement of the open area in backs 934c near the tops of the racks. Air passageways 960 connect these openings to enclosed ceiling area 950 which leads to air conditioning unit 952 that cools the air and blows it back into the data center so that it can enter the perforated front of racks 910a and 910b. Air-moving devices 962 may not be necessary if there is sufficient pressure drop in ceiling area 950 to draw the heated air up into area 950; this is a detail that depends on the particular arrangement of the data center.

The invention accomplishes efficient cooling of electronic equipment in the housing without the need for deep rear doors having internal fans and ducting that withdraws heated air out of the housing and blows it out of the top of the door, of the type known in the art. The invention thus accomplishes efficient cooling without increasing the depth of the equipment rack up to the height B off of the floor at which the air passageway projects from the housing. This allows racks to be separated by a minimum width A. Dimensions A and B may be dictated by local, state and/or federal regulations, such as the Americans with Disability Act (ADA) and/or the National Fire Protection Association (NFPA) codes. In one example, regulations require an 80″ unobstructed headroom height (which can establish the minimum height “B”), and a minimum aisle width of 36″ (which can establish the minimum inter-rack spacing “A”). Regardless of the minimum dimensional needs, the invention accomplishes a maximum density of equipment housings in a data center area, as it does away with the need for thickened front and/or rear doors that have been necessary to accommodate air-handling equipment.

The invention also provides improved systems and methods for heat containment and cold air isolation in data centers.

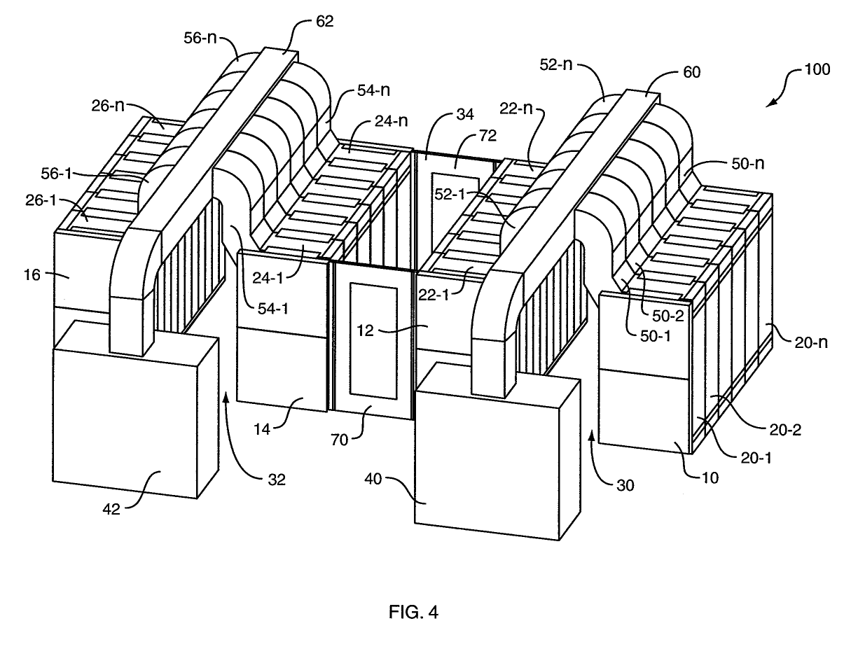

With reference to FIGS. 4, 5 and 6, in a preferred embodiment, a data center 100 comprises one or more rows 10, 12, 14 and 16 of adjacent cabinets or enclosures, such as cabinets 20-1, 20-2 . . . 20-n in row 10; cabinets 22-1, 22-2 . . . 22-n in row 12; cabinets 24-1, 24-2 . . . 24-n in row 14; and cabinets 26-1, 26-2 . . . 26-n in row 16.

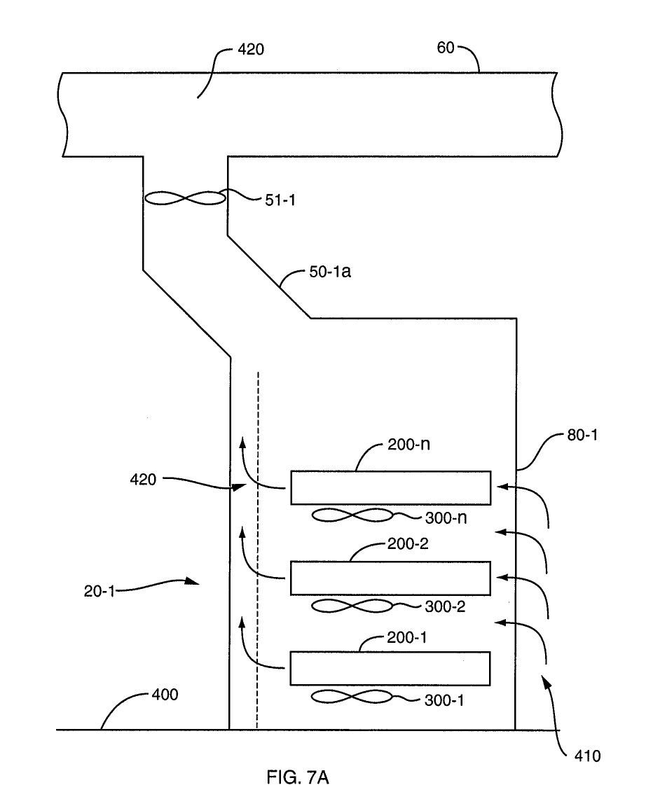

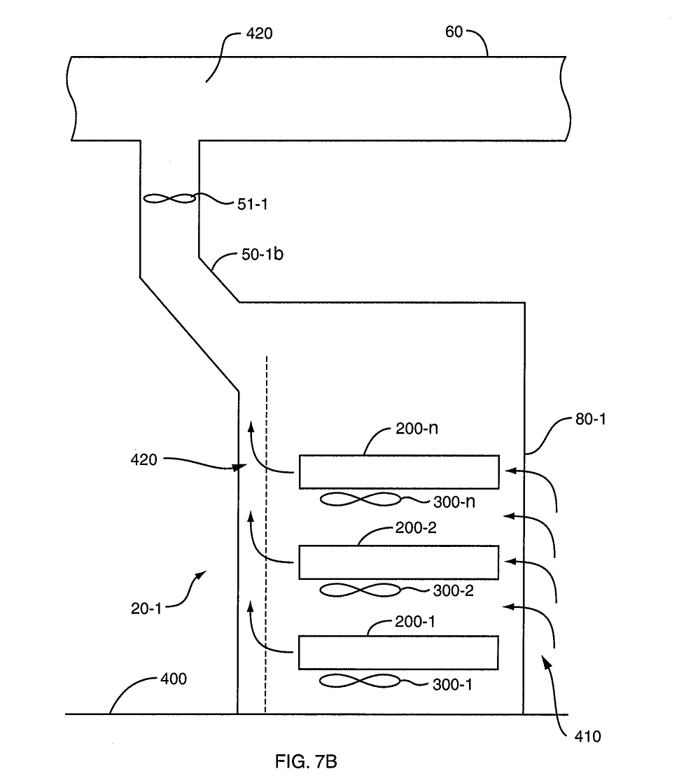

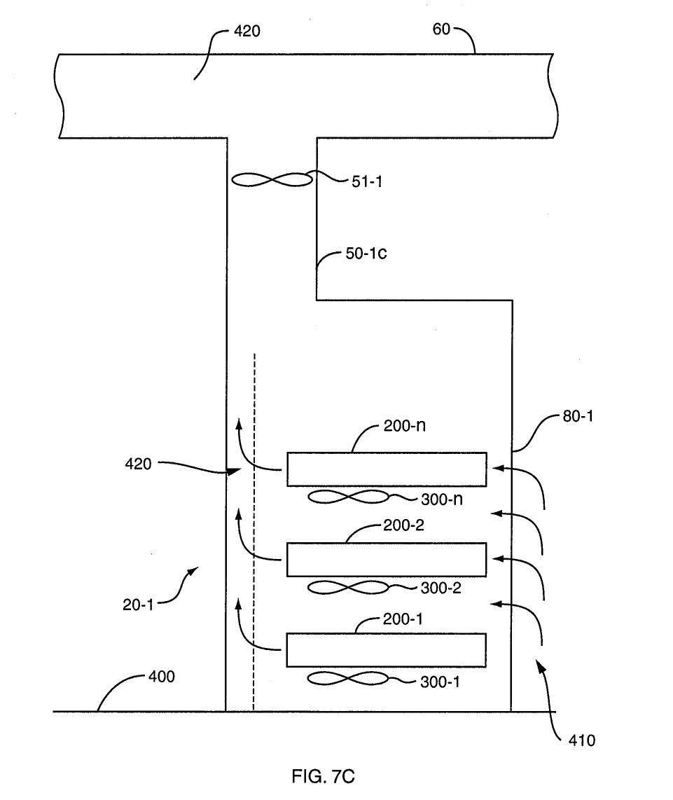

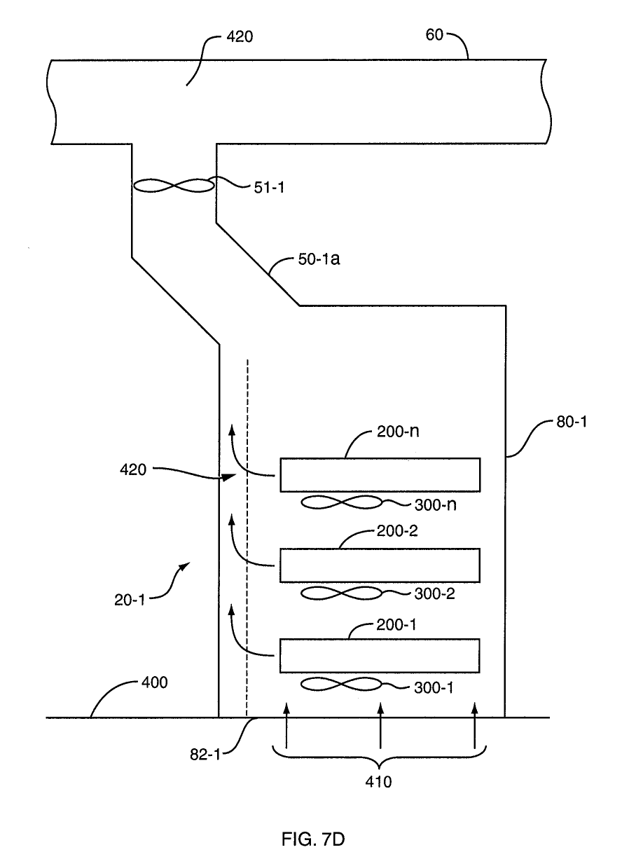

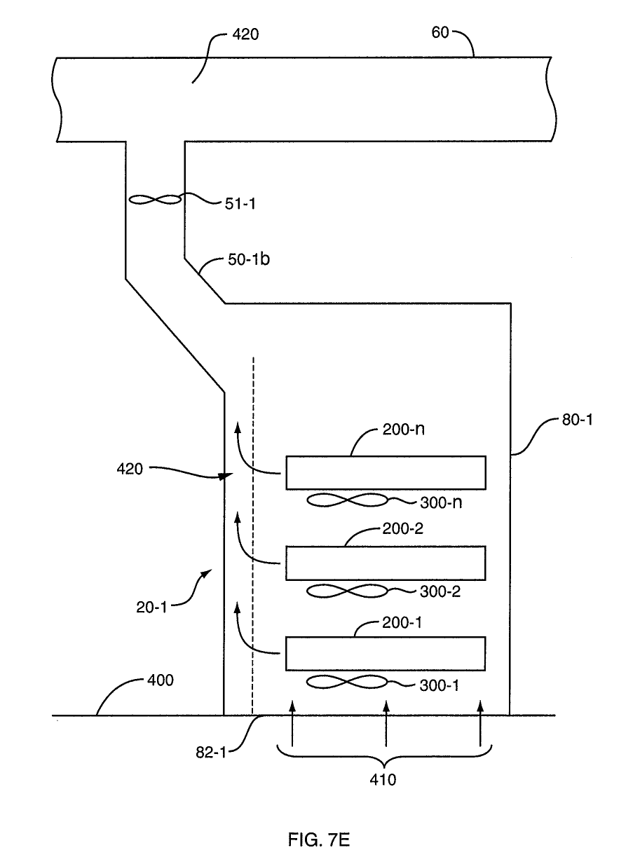

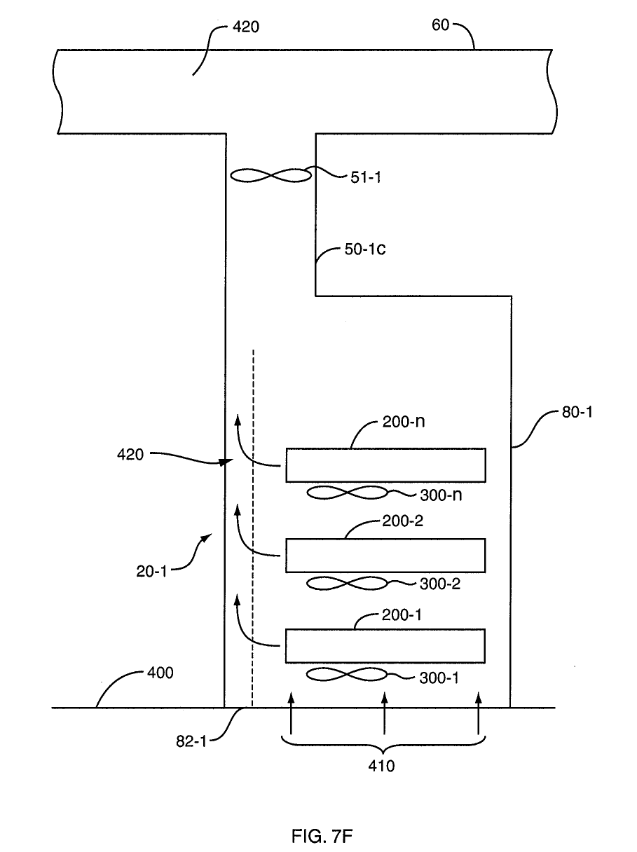

With reference to FIGS. 7A, 7B and 7C, each cabinet, such as cabinet 20-1, may contain one or more heat-generating computer or IT equipment elements 200-1, 200-2 . . . 200-n, including but not limited to file servers, database servers, data processors, and network routers. As is known in the art, each cabinet may include a perforated front panel or door, such as door 80-1 of cabinet 20-1, to allow cool air to circulate into and within the cabinets. Each cabinet may also include a solid rear or back door. Each cabinet may also include one or more fans, such as fans 300-1, 300-2 . . . 300-n, to create a forced airflow within the cabinet.

In alternate embodiments, as shown in FIGS. 7D, 7E and 7F, each cabinet, such as cabinet 20-1, may include a solid front panel or door, 80-1, and a substantially open or perforated bottom, such as bottom 82-1, through which cool air circulates into the cabinets.

With further reference to FIGS. 4, 5 and 6, in a preferred embodiment, the heat-generating equipment in the cabinets is cooled by cool air generated by one or more air conditioning units 40 and 42, although the number of air conditioning units may vary as required by the characteristics of the data center. In alternate embodiments, the heat-generating equipment in the cabinets is cooled by cool air generated by the building's air conditioning system, or a combination the building's air conditioning system and the data center's dedicated air conditioning units 40 and 42.

As shown in FIGS. 7A, 7B and 7C, the cool air 410 may be supplied from the air conditioning units 40 and 42 through the perforated tiles of an elevated floor 400 in data center 100. Alternatively, or in addition, the cool air may be piped directly into the data center 100 using systems and methods known in the art. For example, in an embodiment, the cool air may be ducted directly into the cold aisles of the data center from above, rather than through the perforated tiles of an elevated floor.

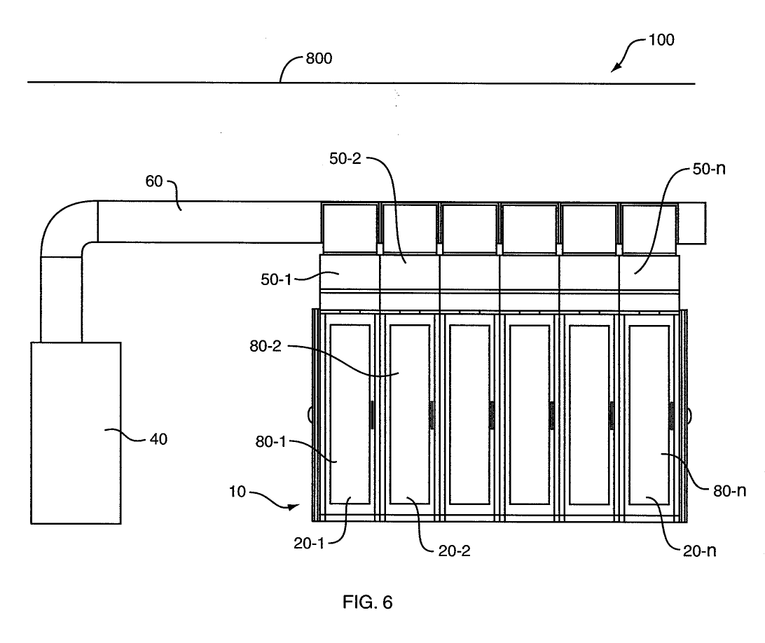

In a preferred embodiment, and with further reference to FIGS. 6 and 7A, 7B and 7C, cool air enters the cabinets through perforated panels or doors, such as the perforated doors 80-1, 80-2 . . . 80-n located at the front of the cabinets 20-1, 20-2 . . . 20-n. In alternate embodiments, and with further reference to FIGS. 7D, 7E and 7F, cool air enters the cabinets through substantially open or perforated bottoms, such as bottoms 82-1, 82-2 . . . 82-n.

The air heated by the computer equipment, such as computer equipment 200-1, 200-2 . . . 200-n in cabinet 20-1, exits the cabinet through the back and/or top of the cabinet. In a preferred embodiment, and as shown in FIGS. 4, 5, 6 and 7A-7F, heated air 420 is contained and directed through the chimneys connected to the top, rear or top and rear of the cabinets, such as chimneys 50-1, 50-2 . . . 50-n, coupled to cabinets 20-1, 20-2 . . . 20-n; chimneys 52-1, 52-2 . . . 52-n, coupled to cabinets 22-1, 22-2 . . . 22-n; chimneys 54-1, 54-2 . . . 54-n, coupled to cabinets 24-1, 24-2 . . . 24-n; and chimneys 56-1, 56-2 . . . 56-n, coupled to cabinets 26-1, 26-2 . . . 26-n. The chimneys prevent the heated air exiting the cabinets from mixing with the cooler air entering the cabinets, thus isolating the two airflows. As shown in FIGS. 7A and 7D, in a preferred embodiment, the chimneys, such as chimney 50-1a, may be mounted at the top and rear of cabinet 20-1. In alternate embodiments, the chimneys, such as chimney 50-1b, may be mounted at the rear of cabinet 20-1, as shown in FIGS. 7B and 7E, or at the top of cabinet 20-1, as shown in FIGS. 7C and 7F. As shown in FIGS. 7A, 7B, 7D, and 7E, the chimneys may extend out from the rear of the cabinet, at an angle in the range of approximately zero to 180 degrees, and preferably about 45 degrees. The chimneys may also include one or more fans, such as fan 51-1.

In a preferred embodiment, heated air may be returned to the air conditioning units 40 and 42 through ducts 60 and 62, respectively, which are located below the ceiling 800 and are coupled to the chimneys, as shown in FIGS. 4, 5 and 6. Returning the heated air directly to the air conditioning units allows the air conditioning units to operate more efficiently. In preferred embodiments, ducts 60 and 62 may include baffles and/or fans (not shown) to control the air pressure within the ducts. The ducts 60 and 62 may be instrumented to monitor the air pressure, and the baffles and/or fans may be manually or remotely controlled, using methods known in the art. In additional embodiments, baffles and/or fans may also be located in the air conditioning systems' return plenums, which may also be instrumented to monitor the air pressure, and may also be manually or remotely controlled.

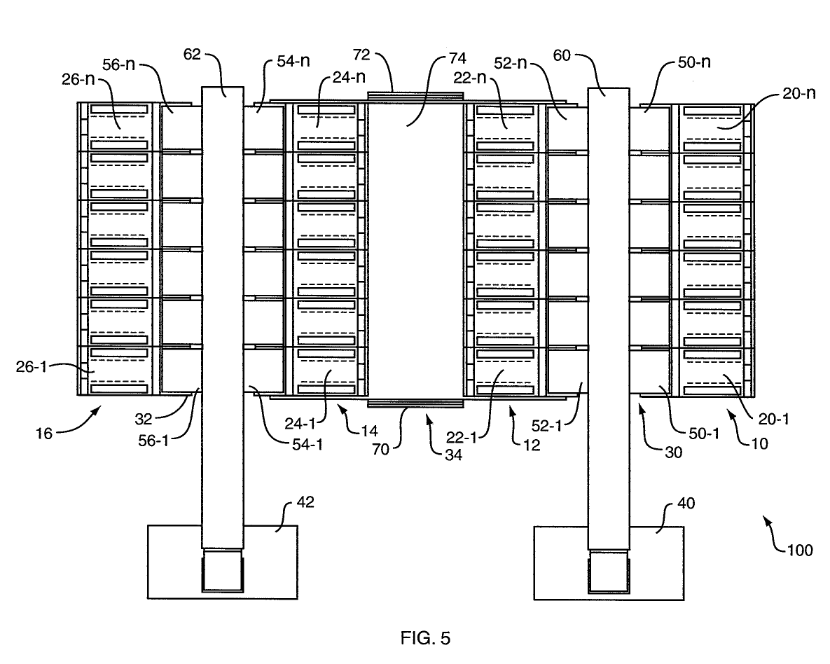

With further reference to FIGS. 4 and 5, rows 10, 12, 14 and 16 may be arranged to form aisles. In a preferred embodiment, the fronts of the cabinets in rows 12 and 14 face each other to form a cold aisle 34. Correspondingly, the backs of the cabinets in row 12 face the backs of the cabinets in row 10 to form hot aisle 30, and the backs of the cabinets in row 14 face the backs of the cabinets in row 16 to form hot aisle 32.

As shown in FIGS. 4 and 5, cold aisle 34 may be isolated from the rest of the data center 100 by adding baffles to obstruct the flow of warm air into the cold aisle, such as doors 70 and 72 at opposing ends of the cold aisle 34. In alternate embodiments, one of the doors 70 or 72 may be replaced with a fixed panel. In addition, one or both of the doors 70 or 72 may include a translucent panel as a window to allow light to enter the cold aisle. The translucent panel may be Plexiglas®, but other materials, including but not limited to glass and Lucite®, are contemplated and within the scope of the invention.

In addition, in a preferred embodiment, the cold aisle 34 may be further isolated from the rest of the data center 100 by adding an optional roof or cover 74. Roof 74 is preferably made of a translucent material, such as Plexiglas®, but other materials, including but not limited to glass and Lucite®, are contemplated and within the scope of the invention.

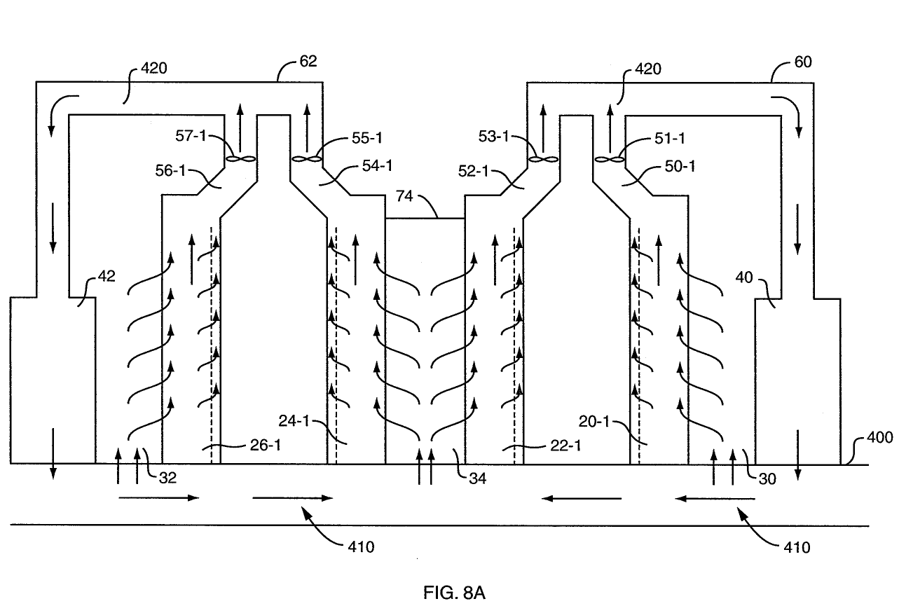

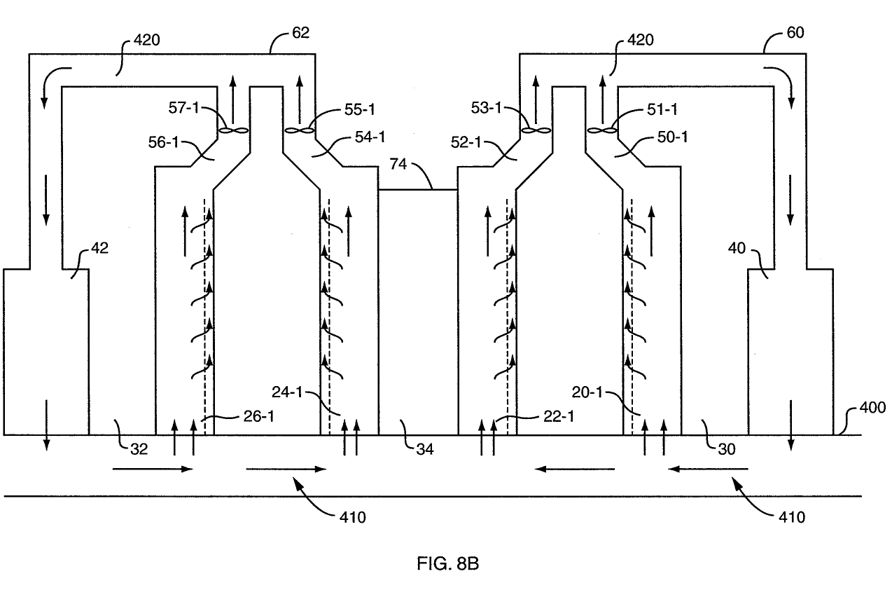

FIGS. 8A and 8B are representations of the airflow management, and specifically the combination of cold air isolation and heat containment, of the data center shown in FIGS. 4, 5, and 6, and described above.

As shown in FIGS. 8A and 8B, and with reference to FIGS. 4, 5 and 6, cooled air 410 from air conditioning units 40 and 42 enters the data center 100 through perforated tiles in raised floor 400, and/or through the bottoms of the cabinets. Alternatively, or in addition, cooled air 410 from air conditioning units 40 and 42 may be ducted directly into data center 100. For example, cooled air 410 may be ducted directly into the cold aisles of the data center from above, in addition to, or instead of, entering the data center 100 through the perforated tiles in raised floor 300 and/or through the bottoms of the cabinets.

With reference to FIG. 8A, cooled air 410 is drawn through the fronts of the cabinets, such as the fronts of the cabinets 22-1 and 24-1 in rows 12 and 14 located in cold aisle 34, and the fronts of cabinets 26-1 and 20-1. In an alternate embodiment, as shown in FIG. 8B, cooled air 410 is drawn through the bottoms of the cabinets, such as the bottoms of the cabinets 22-1 and 24-1 in rows 12 and 14 located in cold aisle 34, and the bottoms of cabinets 26-1 and 20-1.

As shown in FIGS. 8A and 8B, the cooled air circulates within the cabinets, and warmed air 420 exits the interior of the cabinets at the top of the cabinets. Warmed air 420 is directed through the chimneys, such as chimneys 50-1, 52-1, 54-1 and 56-1, and returned through ducts 62 and 60 to air conditioning units 40 and 42. In a preferred embodiment, the chimneys include one or more fans, such as 51-1, 53-1, 55-1 and 57-1, to facilitate the circulation of air through the cabinets.

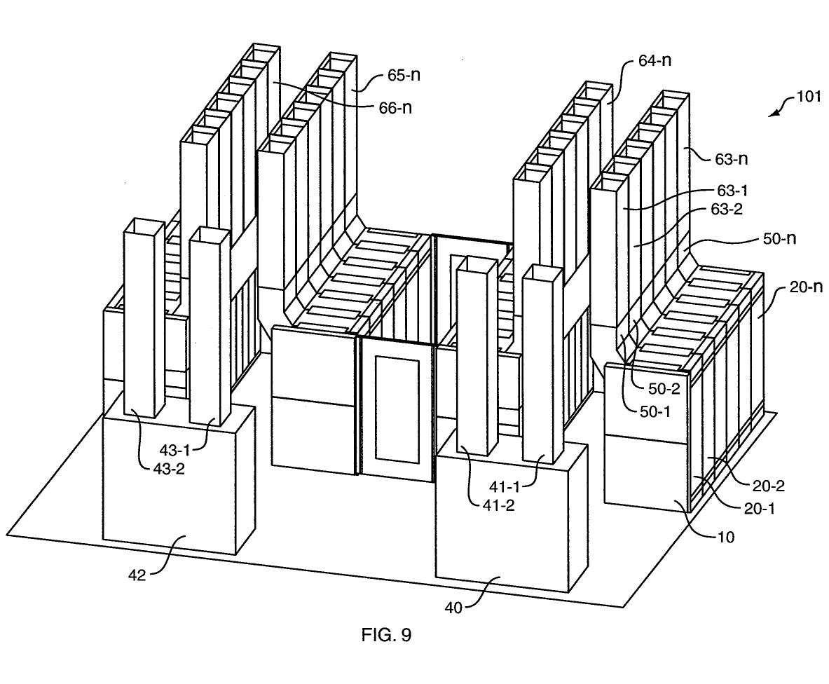

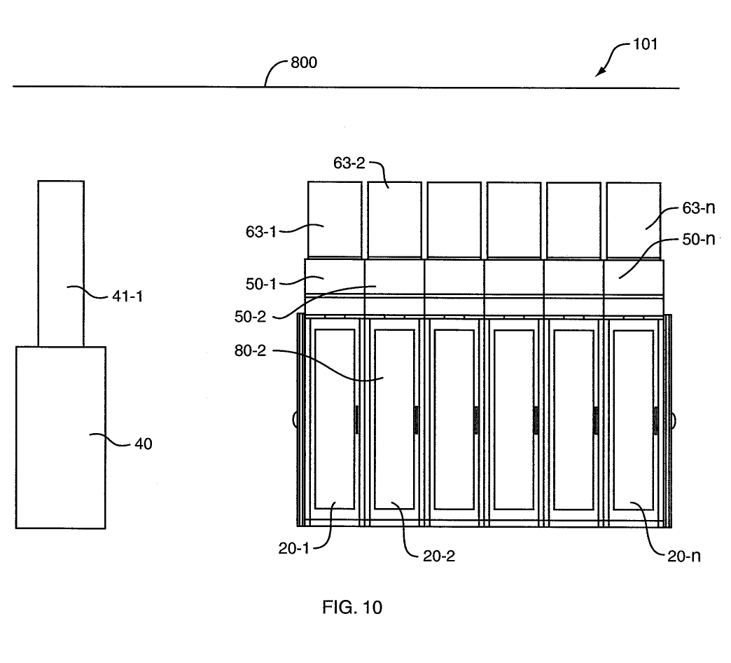

In an alternate embodiment, and as shown in FIGS. 9 and 10, the warm air from the cabinets is exhausted high into the room through vertical ducts, such as ducts 63-1, 63-2 . . . 63-n of cabinets 20-1, 20-2 . . . 20-n. The ducts are located below the ceiling 800. The computer room air conditioners 40 and 42 intake the warm air through intake ducts 41-1, 41-2, 42-1, and 42-2. Ducts 41-1, 41-2, 42-1, and 42-2 may contain baffles and/or fans (not shown) to control the air pressure within the ducts. The ducts may be instrumented to monitor the air pressure, and the baffles and/or fans may be manually or remotely controlled, using methods known in the art. The number of air conditioners and air intake ducts may vary, according to the characteristics of the data center 101. In additional embodiments, the heat-generating equipment in the cabinets is cooled by cool air generated by the building's air conditioning system, or a combination of the building's air conditioning system and the data center's dedicated air conditioning units 40 and 42.

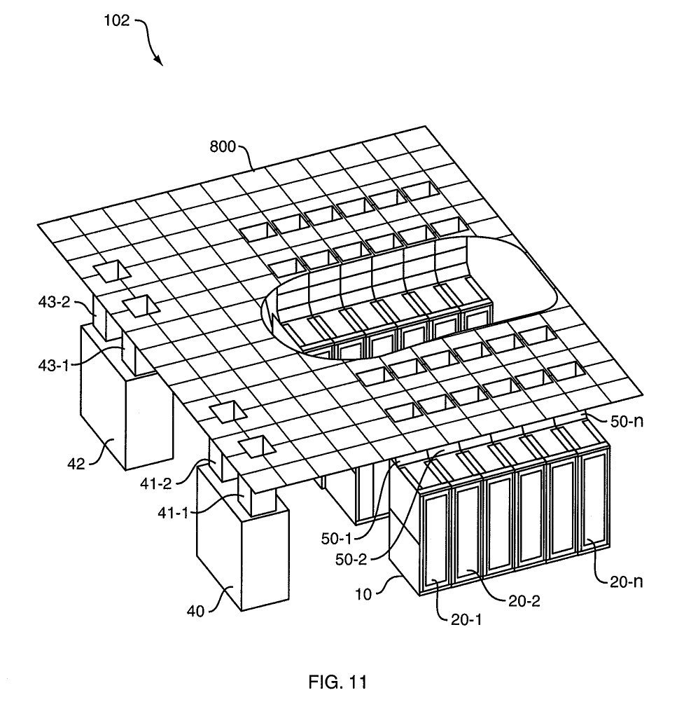

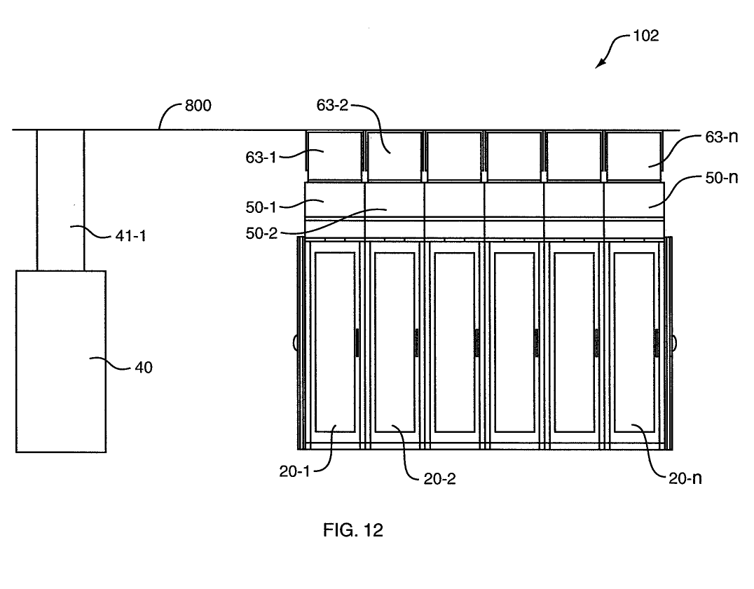

In yet another embodiment, and as shown in FIGS. 11 and 12, the warm air from the cabinets is exhausted into a pressurized ceiling plenum or suspended ceiling 800, through vertical ducts, such as ducts 63-1, 63-2 . . . 63-n of cabinets 20-1, 20-2 . . . 20-n. The computer room air conditioners 40 and 42 intake the warm air through intake ducts 41-1, 41-2, 42-1, and 42-2. The ducts and/or the plenum or ceiling may contain baffles and/or fans (not shown) to control the air pressure within the ducts and/or plenum or ceiling. The ducts and/or plenum or ceiling may be instrumented to monitor the air pressure, and the baffles and/or fans may be manually or remotely controlled, using methods known in the art. The number of air conditioners and air intake ducts may vary, according to the characteristics of the data center 101.

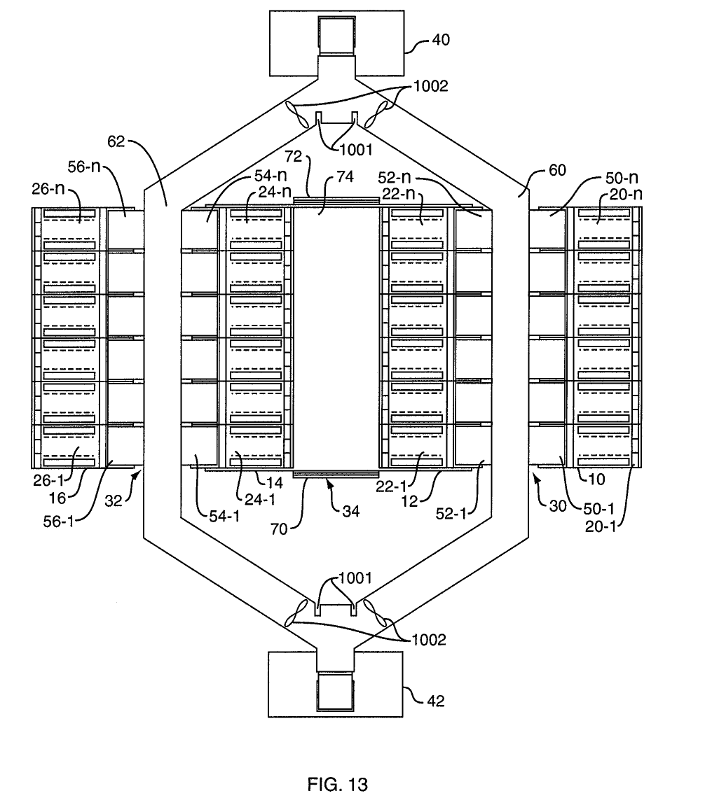

In a preferred embodiment, and as shown in FIG. 13, each air conditioning unit 40 and 42 may be configured to selectively service one or more rows of cabinets through the use of baffles 1001 and/or fans 1002. For example, baffles 1001 and/or fans 1002 may be used to control the return of heated air from cabinets in rows 14 and 16 to air conditioning unit 40 and heated air cabinets in rows 10 and 12 to air conditioning unit 42. In the event of a malfunction, such as a failure in air conditioning unit 40, baffles and/or fans may be used to control the return of heated air from cabinets in rows 14 and 16 to air conditioning unit 42. For example, if air conditioning unit 40 fails, baffles 1001 may be closed to shut off the passage leading to air conditioning unit 42, and fans 1002 may be turned on to draw air through the ducts towards air conditioning unit 42. Note that the configuration of air conditioning units and ductwork is not limited to the “Y” configuration shown in FIG. 10, and that alternate configurations, such as a “star” configuration, are contemplated and within the scope of the invention.

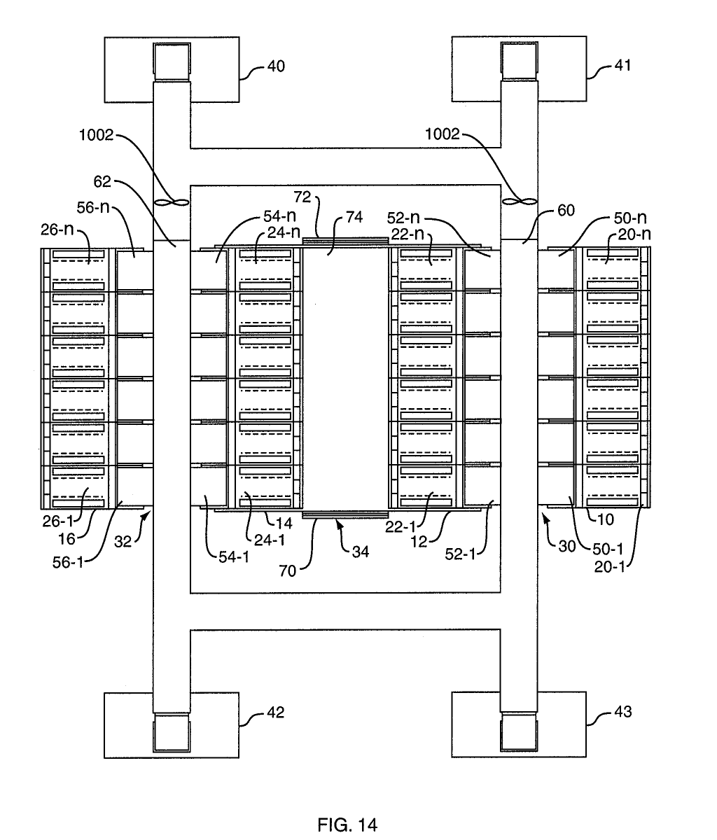

In alternate embodiments, and as shown in FIG. 14, one or more of the air conditioning units 40 and 42 may each have a redundant backup air conditioning unit, such as units 41 and 43. As with the embodiment shown in FIG. 13, each air conditioning unit 40, 41, 42 and 43 may be configured to selectively service one or more rows of cabinets through the use of baffles 1001 and/or fans 1002.

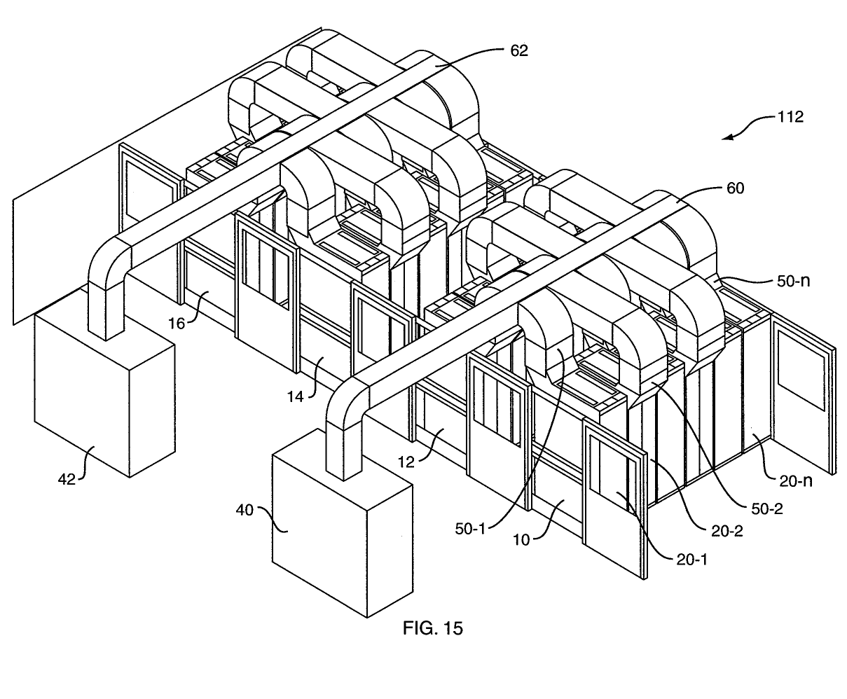

FIG. 15 is a perspective representation of a data center 112 according to an alternate embodiment of the invention, in which the cabinets are not arranged to form hot aisles and cold aisles, and warmed air from the cabinets is exhausted into a below-ceiling duct.

As shown in FIG. 15, data center 112 is similar to the data center 100 shown in FIG. 4, with one or more rows 10, 12, 14 and 16 of cabinets and one or more air conditioning units 40 and 42. Unlike FIG. 4, though, the rows of cabinets 10, 12, 14 and 16 are arranged in an alternating pattern, such that the front panel or door of cabinet 20-1 is adjacent to the rear panel or door of cabinet 20-2. As further shown in FIG. 15, and as described previously with reference to FIGS. 4 through 6 and 7A through 7F, heated air within each cabinet is contained and directed through the chimneys 50-1, 50-2 . . . 50-n connected to the top, rear, or top and rear of the cabinets 20-1, 20-2 . . . 20-n. The heated air is returned to the air conditioning units 40 and 42 through ducts 60 and 62, respectively, which are located below the ceiling and coupled to the chimneys.

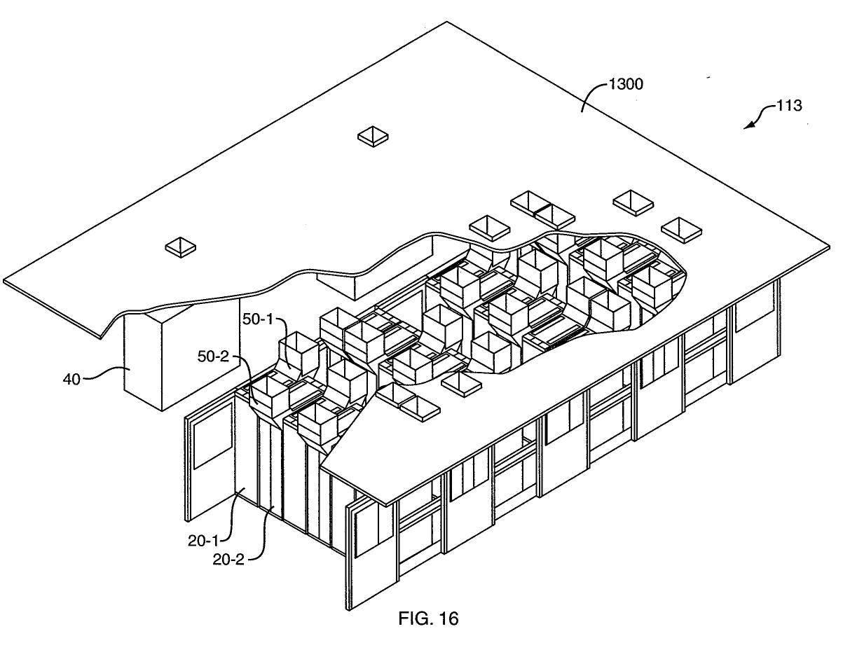

FIG. 16 is a perspective representation of a data center 113 according to an alternate embodiment of the invention, in which the cabinets are arranged as described above for FIG. 15. As shown in FIG. 16, however, warmed air from the cabinets is exhausted into a pressurized ceiling plenum or suspended ceiling 1300. Note that the arrangement of cabinets in FIGS. 15 and 16 is not limited to this particular embodiment, however, and other cabinet configurations are within the scope of the invention.

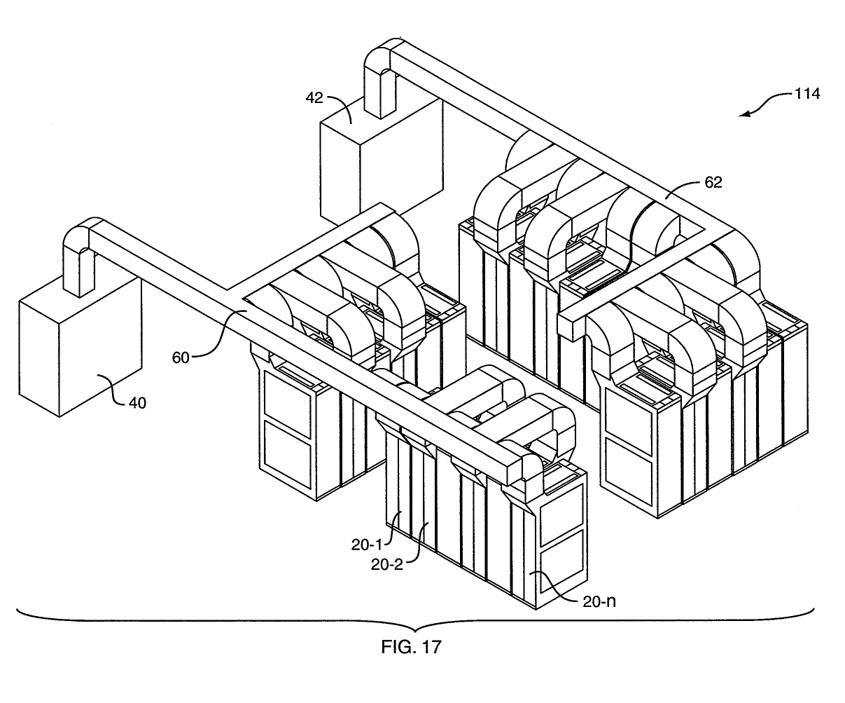

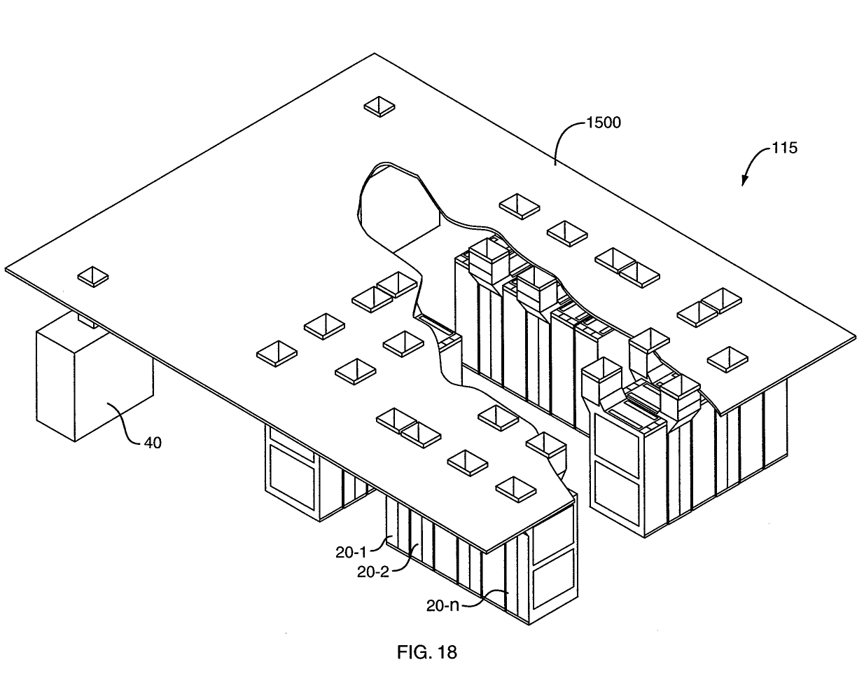

FIG. 17 is a perspective representation of a data center 114 according to an alternate embodiment of the invention, in which the cabinets are not arranged to form hot and cold aisles, but are configured in a “chaos” layout, and warmed air from the cabinets is exhausted into a below-ceiling duct. FIG. 18 is a perspective representation of a data center 115 according to an alternate embodiment of the invention, in which the cabinets are arranged as described above for FIG. 17. As shown in FIG. 18, however, warmed air from the cabinets is exhausted into a pressurized ceiling plenum or suspended ceiling 1500. Note that the arrangement of cabinets in FIGS. 17 and 18 is not limited to this particular embodiment, however, and other cabinet configurations are within the scope of the invention.

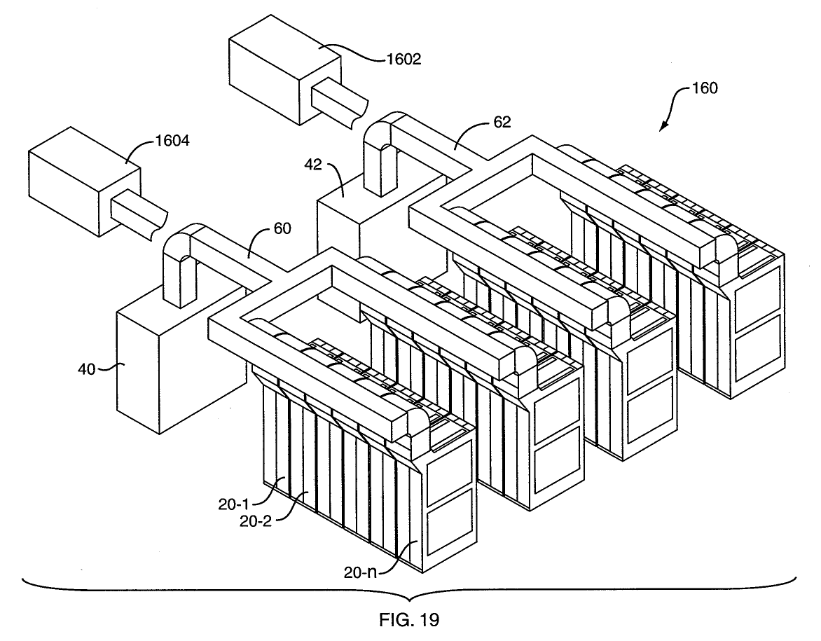

FIG. 19 is a perspective representation of a data center 160 according to an alternate embodiment of the invention, in which the heated air is aggregated, and one or more air-side economizers 1602 and 1604 may be used to cool the heated air with cool outside air. In this configuration, baffles and/or fans (not shown) may be used to control the return of heated air in ducts 60 and 62 to air conditioning units 40 and 42, in addition to, or instead of, air-side economizers 1602 and 1604.

In alternate embodiments, locations and equipment in the data center may be instrumented to monitor and control temperature, air pressure, power consumption, efficiency, and overall availability, using systems and methods known in the art.

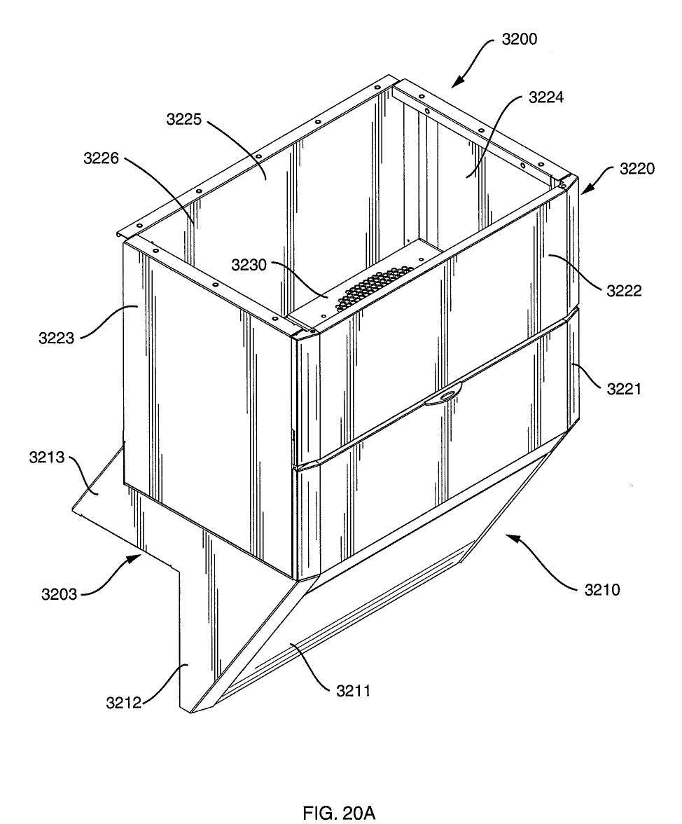

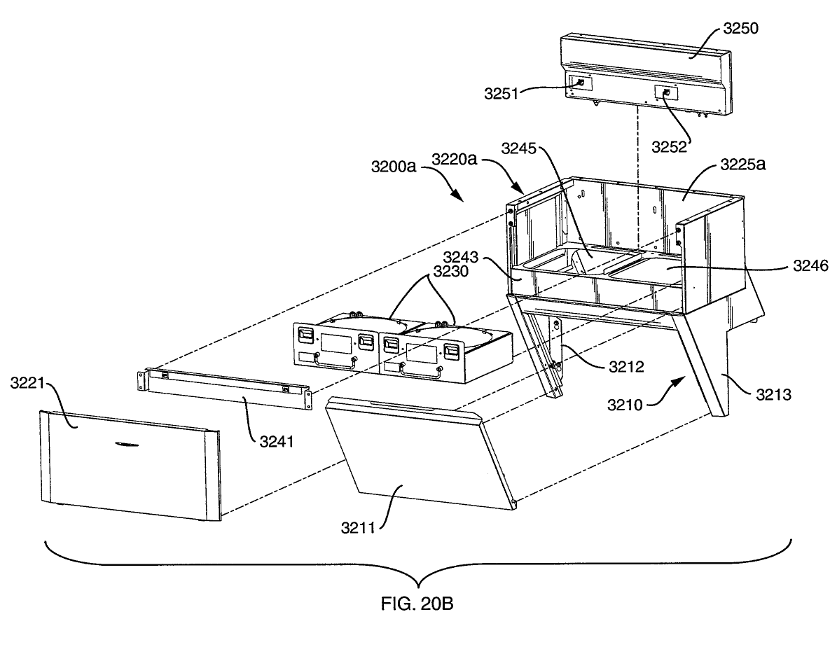

Alternative embodiments of an assembly for extracting heat from a housing are shown in FIGS. 20A through 24. Some variations of different aspects of this embodiment are shown in the various figures, as will be described. These embodiments are especially designed to be used as an after-market product, as a replacement for the rear panel or rear door(s) of an electronics rack. In some cases the assembly also replaces the top panel of a rack. One aspect of this embodiment comprises chimney 3200, FIG. 20A. Chimney 3200 includes a first section 3210 that is adapted to be coupled to the housing such that the chimney encompasses the top rear corner of the housing, and thus is in fluid communication with any opening(s) at the back of the top of the housing and any opening(s) at the top of the back of the housing. The chimney thus conducts heated air leaving the housing (by convection or under fan assist) through such openings. The chimney is like a duct and is largely open, to allow it to conduct heated air exiting the housing through these openings to leave the chimney, as described above. An alternative to a passive chimney is an active chimney with one or more fans, as will be described.

First section 3210 at its lower end forms a coupling portion 3203 that is generally L-shaped as defined by horizontal and vertical members, so that it closely conforms to the top back corner of the rectangular prism-shaped housing, which for example may be a server rack as described above. Thus, chimney 3210 fits tightly over and follows the contour of the top back corner of the housing. This allows hot air exiting the housing through its top back corner to move up into the chimney rather than leaking into the room. In this embodiment, sidewalls 3212 and 3213 also define this “L-shape.” Rear wall 3211 is angled upward and outward with respect to the back of the enclosure (i.e., with respect to the vertical) at an angle of less than 90 degrees, preferably about 45 degrees.

Second section 3220 generally has the shape of a rectangular duct. This embodiment of the chimney is active, carrying one or more fan trays 3230 within second section 3220. Access to the fan trays is provided through hinged door 3221. Panel 3222 is a fixed panel. Section 3220 is completed by sides 3223 and 3224, and front wall 3225. Section 3220 defines chimney exit 3226 that is typically coupled to another structure such as a suspended ceiling or another duct that leads to an air conditioning unit that cools the air and returns it either to the room or directly to the housings/enclosures, as is known in the art. The angled and rectangular shapes are not limitations, as other shapes and arrangements are possible depending on the enclosure and the room layout.

More details of the construction of slightly different chimney 3200a are shown in FIG. 20B. Generally square openings 3245 and 3246 are defined in member 3243. In a passive structure, openings 3245 and 3246 can remain as shown, or member 3243 can be removed so that sections 3210 and 3220 are wide open. If one fan was used, only one (larger) opening 3245 or 3246 would be present. In this active embodiment, two fan trays 3230 slidingly engage with the assembly just above openings 3245 and 3246. Panel 3241 is coupled to the front of member 3243 to provide a hinged anchor point for door 3221 that pivots on a horizontal axis about hinges (not shown) carried by member 3241. Electrical supply adaptor 3250 is coupled to the inside of front wall 3225a and defines electrical supply connectors 3251 and 3252 that accept mating push-in electrical connectors in the backs of fan trays 3230 so that the fans are supplied with power when they are pushed into the chimney and mate with these electrical supply connectors. This accomplishes a hot-swappable feature in which one or both fans can be removed and replaced while the device remains in operation, allowing a fan to be replaced without having to affect the operation of the servers or other electronic devices within the enclosure.

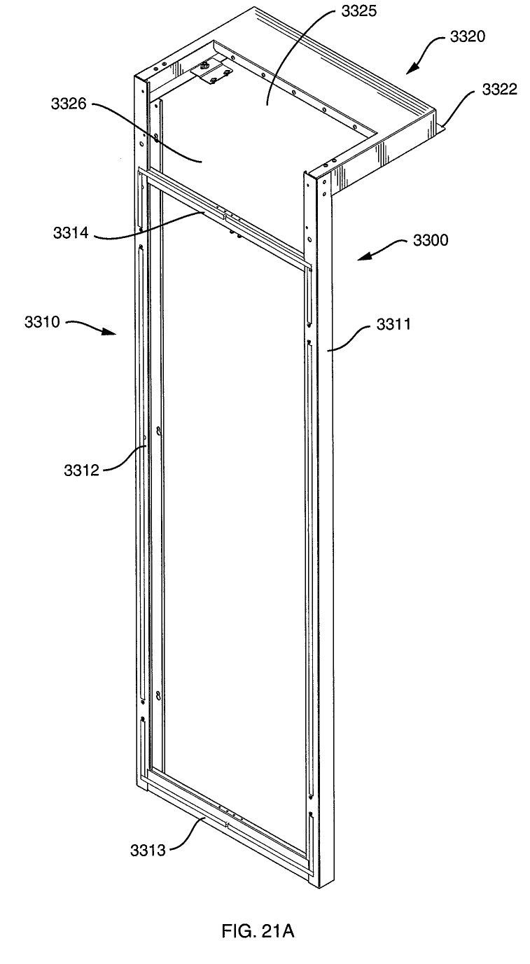

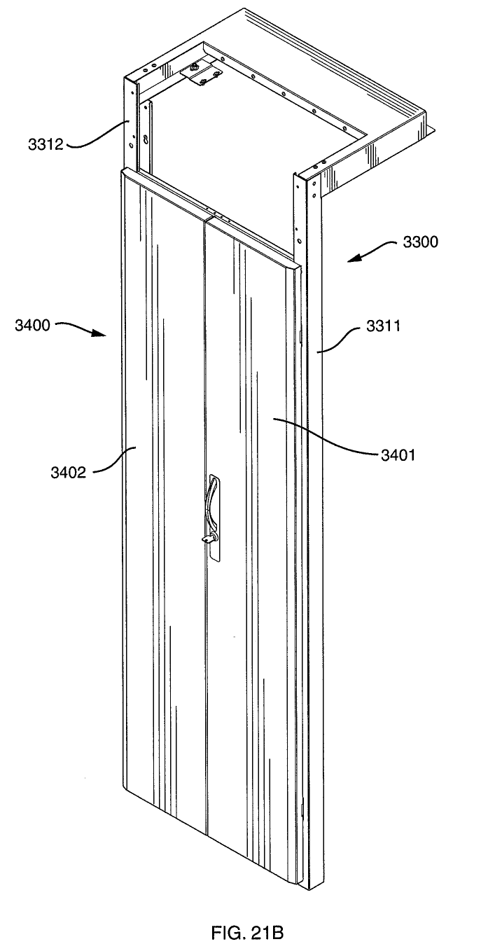

An embodiment of inventive assembly 3600 further comprises intermediate assembly 3300, FIGS. 21A and 21B. Intermediate assembly 3300 comprises intermediate assembly vertical frame member 3310, and intermediate assembly horizontal top portion 3320. Assembly 3600 (and indeed the entirety of the inventive assembly) is preferably fashioned of steel structural members and sheet metal panels, with appropriate fasteners. Frame 3310 comprises right and left side vertical structural members 3311 and 3312 and top and bottom horizontal structural members 3314 and 3313, respectively. Member 3314 defines the bottom extent of second opening 3326 that spans essentially the entire width of the rear of the housing, where the rear and top meet. Top portion 3320 defines the front edge of first opening 3325 at the rear of the top of the enclosure where the top and rear meet, and also spans essentially the entire width of the enclosure. Openings 3325 and 3326 are preferably (but not necessarily) contiguous, in that they are either continuous or are immediately or closely adjacent. For example, if desirable, one or more additional cross members may be located in either of openings 3325 or 3326 or at their intersection without affecting the functionality of the invention, or the openings may be in different locations, or have different sizes and/or shapes. Openings 3325 and 3326 form the entry into chimney 3200. When assembly 3600 is in place, heated air leaving the enclosure from the back of the top and the top of the back will be conducted into chimney 3200. The openings at the top of the back and the back of the top need not be contiguous, nor must both be present, as long as the chimney encompasses at least one of these, and preferably as much open area as possible to facilitate heat transfer out of the enclosure. Also, the openings can be either fully or partially open. For example, the openings could be partially closed by a screen or a perforated panel while still allowing heated air to escape the housing and enter the chimney.

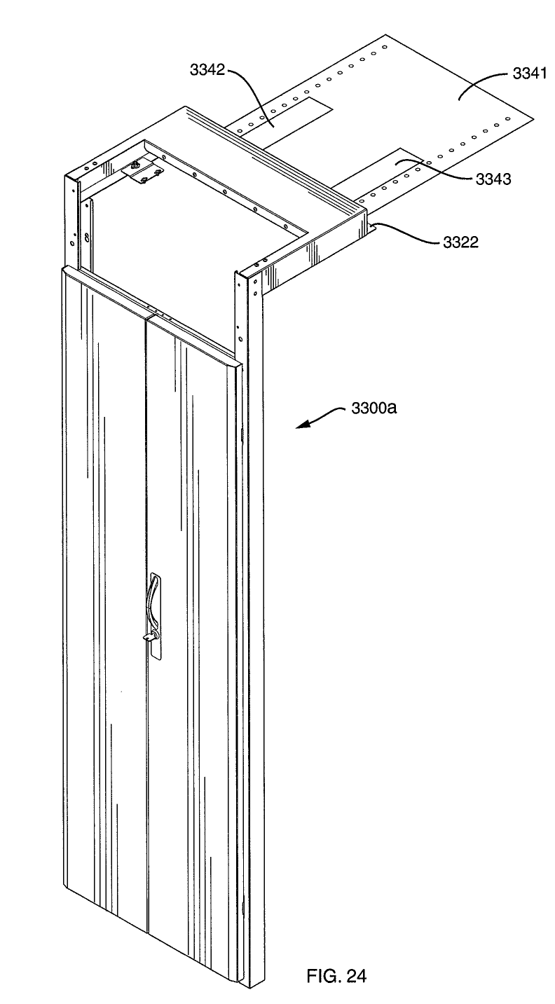

In this embodiment, the back portion of the inventive assembly also comprises one or more doors to provide access to the housing interior through the back, although doors are not necessary and the back could be essentially closed, for example by a solid panel rather than doors. FIG. 21B shows a matched pair of doors 3401 and 3402 making up door assembly 3400. These doors are mounted to members 3311 and 3312 along vertical hinges (not shown). Intermediate assembly 3300, FIG. 21B, thus comprises essentially the entirety of the back portion of the housing or electronics enclosure, and in this case overlies some of its top portion. Embodiment 3300 is typically used as a replacement for the back of an existing enclosure, and sits on top of the top panel of the housing. Alternative embodiment 3300a, FIG. 24, includes top panel 3341 that is coupled to flange 3322 so that member 3320 and member 3341 comprise essentially the entirety of the top portion of the housing. Thus, embodiment 3300a will typically replace both the top and back portions of an existing housing. Embodiment 3300a shows optional openings 3342 and 3343 that can accept brushes or other permeable structures that allow cabling to be run through the top while maintaining the top essentially solid except for opening 3325, so that heated air exits the top of the enclosure through opening 3325 and is thus conveyed by the chimney, rather than escaping into the room housing the enclosure.

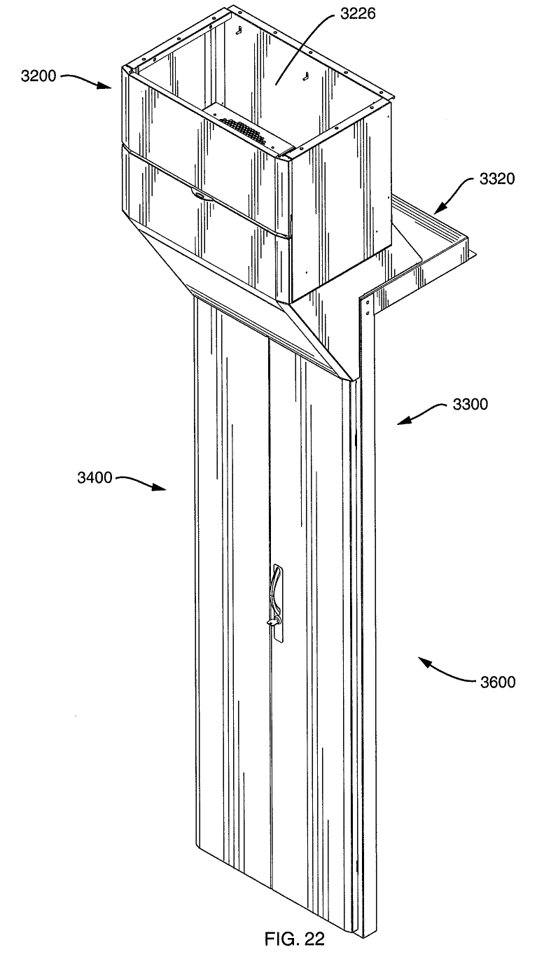

FIG. 22 shows chimney 3200 coupled to intermediate assembly 3300, along with doors 3400, together making up embodiment 3600 of the inventive assembly for extracting heat from a housing. Embodiment 3600 can be sized and shaped to replace the back of an existing housing for electronic equipment. This allows the functionality of the chimney to be added to an existing housing. Embodiment 3600 can thus accomplish additional cooling air flow in a housing, thus allowing existing housings to carry more heat-generating electronic devices.

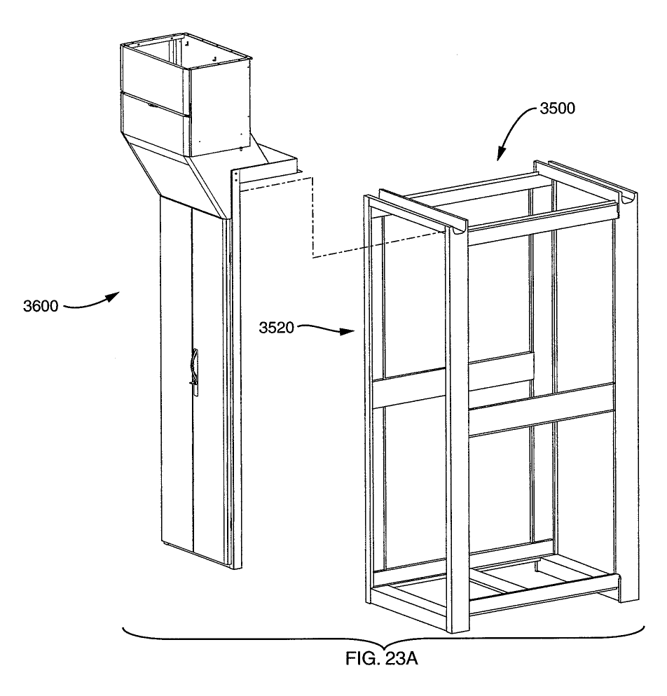

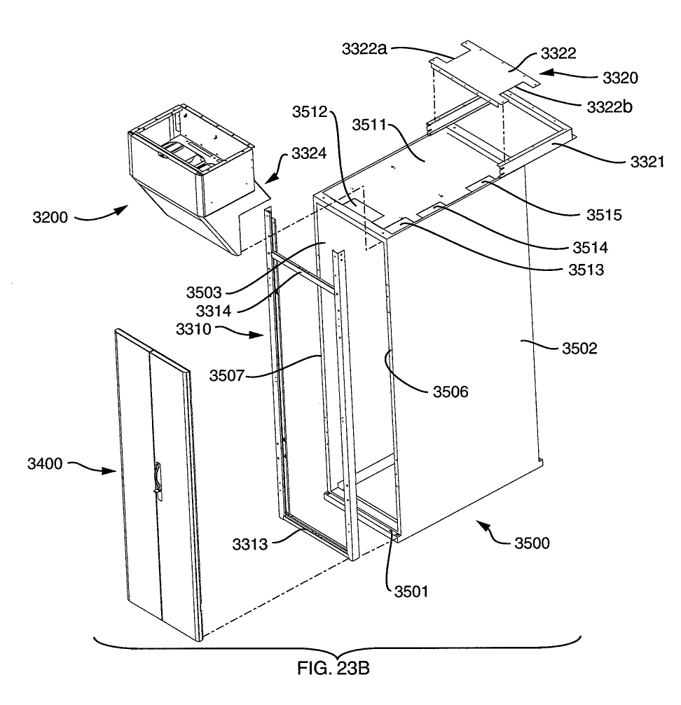

FIGS. 23A and 23B show more detail of the construction of one housing with which this embodiment of the invention can be used, such as the “Paramount” enclosure detailed above. Cabinet frame 3520 carries essentially solid side panels 3502 and 3503 and defines right and left side rear vertical support surfaces 3506 and 3507 to which intermediate assembly frame member 3310 is attached. Rear cross member 3313 sits on and is attached to lower ledge 3501.

FIG. 23B is an exploded view of the inventive assembly used with a housing having an existing top panel 3511 that defines relatively small openings 3512-3515. The back door(s) or back panel (not shown) is removed. The inventive assembly is then fastened to the cabinet, and essentially replaces the back doors and sits over (rather than replacing) enclosure top panel 3511. Frame 3310 is fastened to members 3506, 3507 and 3501. Members 3321 and 3322 make up portion 3320. “U”-shaped frame member 3321 is fastened to the upper ends of frame 3310. Partial cover member 3322 sits on top of member 3321; optional cutouts 3322a and 3322b are shown to accommodate wiring passing through the top of the cabinet. Rear flange 3323 is coupled to front flange 3324 of chimney 3200. This creates assembly 3600. Air is drawn out of enclosure 3500 through opening 3326 created between member 3314 and top 3511, and also through any of openings 3512-3515 that are encompassed by chimney 3200.

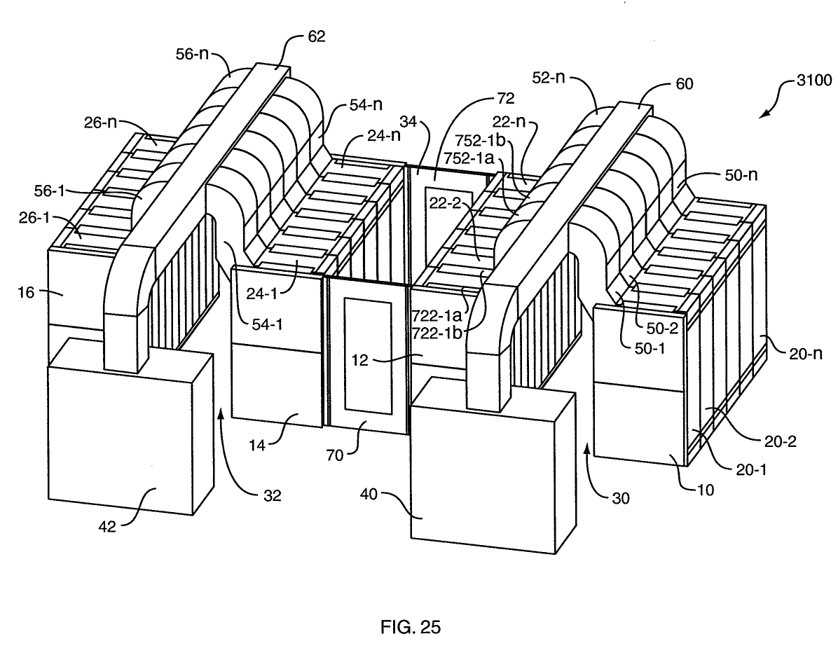

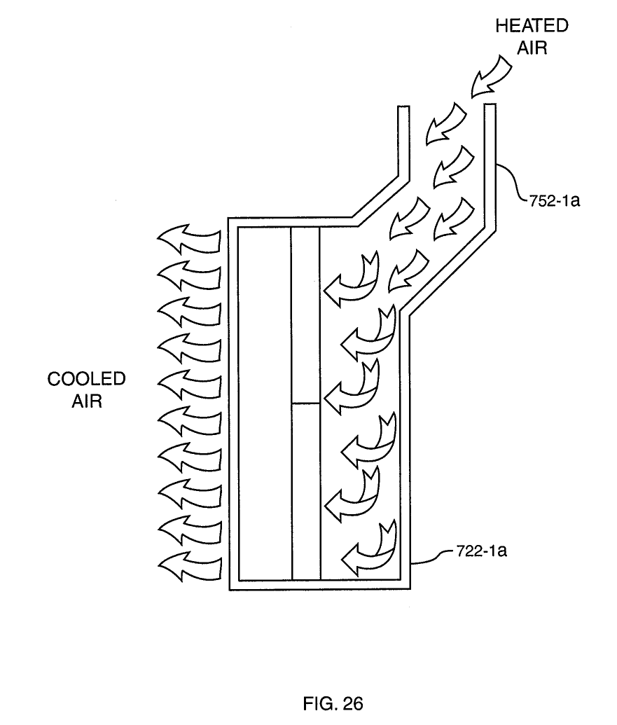

In an additional preferred embodiment, one or more in-line air conditioning units may be co-located with the equipment cabinets or enclosures. While not a limitation of the invention, these in-line air conditioning units are typically one-half the width of an equipment cabinet, such that two in-line air conditioning units may occupy the space of one equipment cabinet. For example, cabinet 22-1 of data center 100, shown in FIG. 4, may be replaced by two in-line air conditioning units 722-1a and 722-1b in data center 3100, as shown in FIG. 25. As with the cabinets 22-2 . . . 22-n in row 12, in-line air conditioning units 722-1a and 722-1b may be coupled to duct 60 via flues or ducts 752-1a and 752-1b, respectively. Unlike the equipment cabinets however, the in-line air conditioning units draw heated air from duct 60. The in-line air conditioning units 722-1a and 722-1b cool the air drawn through the flues or ducts 752-1a and 752-1b, and return the cooled air to cold aisle 34, as shown in FIG. 26.

The equipment cabinet chimneys, such as chimney 22-1, and the in-line air conditioning unit flues or ducts, such as flues or ducts 752-1a and 752-1b, may be of the type shown in FIGS. 20A and 20B as chimney 3200 and described above. In the case of an active flue or duct used with an in-line air conditioner, however, the one or more fan trays 3230, are inverted, such that the fans draw heated air from duct 60 into the interior of the in-line air conditioning unit. Note also that the dimensions of the flue or duct 752-1a and 752-1b may be adjusted to accommodate the smaller width of the in-line air conditioning unit, as compared to the width of a typical equipment cabinet.

In additional embodiments, assembly 3600, as shown in FIGS. 21A, 21B, 22, 23A, 23B and 24, and described above, may be used to replace the rear panel or rear door of an equipment cabinet, such as cabinet 22-2, or the rear panel or rear door of an in-line air conditioning unit, such as unit 722-1a or 722-1b. In some cases, assembly 3600 may also replace the top panel of the equipment cabinet or the in-line air conditioning unit. The claims should not be read as limited to the described order or elements unless stated to that effect. Therefore, all embodiments that come within the scope and spirit of the following claims and equivalents thereto are claimed as the invention.

It should be understood that the embodiments described herein are exemplary and do not limit the scope of the invention, and that various modifications could be made by those skilled in the art that would fall under the scope of the invention. The scope of the invention is set forth in the claims.

What is claimed is:

1. An assembly for supplying heated air to a housing with an interior that is adapted to hold air conditioning equipment, the housing comprising a top portion and a back portion, where the top portion defines a first opening that leads to the housing interior, the first opening located proximate the back of the top portion, where the back portion defines a second opening that leads to the housing interior, the second opening located proximate the top of the back portion, and where the first opening is contiguous with the second opening, the assembly comprising:
a flue external to the housing and adapted to be coupled to the housing such that the flue encompasses and is fluid communication with the first and second openings, the flue defining an inlet for conducting air into the flue and an outlet for conducting air out of the flue and into the housing through the first and second openings.

2. The assembly of claim 1 in which the housing further comprises a support assembly that supports the housing's top and back portions, and the assembly for supplying heated air further comprises an intermediate assembly adapted to be coupled to the support assembly, the intermediate assembly defining at least part of the back portion of the housing, wherein the flue is coupled to the intermediate assembly.

3. The assembly of claim 2 in which the intermediate assembly comprises an intermediate assembly frame member defining at least two sides of the back portion of the housing.

4. The assembly of claim 3 in which the intermediate assembly further comprises a door assembly hingedly coupled to the intermediate assembly frame member, to allow user access to the interior of the housing.

5. The assembly of claim 4 in which the door assembly comprises two doors, one hinged to each side of the intermediate assembly frame member.

6. The assembly of claim 4 in which the door assembly and the intermediate assembly frame member together define the back portion of the housing.

7. The assembly of claim 2 in which the intermediate assembly defines the entire back portion and at least some of the top portion of the housing.

8. The assembly of claim 2 in which the flue comprises a first section that is coupled to the intermediate assembly, the first section extending out from the back portion of the housing at an angle of less than 90 degrees.

9. The assembly of claim 8 in which the back portion of the housing is essentially vertical and the top portion of the housing is essentially horizontal such that the top portion and the back portion are essentially perpendicular and meet to define the top back corner of the housing, and wherein the first section of the flue comprises essentially perpendicular members that define a coupling portion such that when the flue is coupled to the housing the coupling portion fits tightly over the top back corner of the housing.

10. The assembly of claim 9 in which the flue further comprises a second section that extends essentially vertically from the first section.

11. The assembly of claim 10 in which the second section of the flue is an essentially rectangular duct.

12. The assembly of claim 10 further comprising one or more fan trays located within the flue.

13. The assembly of claim 12 in which the fan trays are hot-swappable.

14. The assembly of claim 12 in which the second section of the flue defines a hinged access door to allow access to the fan trays.

15. An assembly for supplying heated air to a housing with an interior that is adapted to hold air conditioning equipment, the housing comprising a top portion and a back portion, where the top portion defines a first opening that leads to the housing interior, the first opening located proximate the back of the top portion, where the back portion defines a second opening that leads to the housing interior, the second opening located proximate the top of the back portion, and where the first opening is contiguous with the second opening, the assembly comprising:
a) an intermediate assembly adapted to be coupled to the support assembly, the intermediate assembly defining at least part of the back portion of the housing and at least part of the top portion of the housing, the intermediate assembly further defining:
i) a first opening extending across substantially all of the width of the top portion of the housing and leading to the housing interior, the first opening located at the back of the top portion, proximate the back portion of the housing; and
ii) a second opening extending across substantially all of the width of the back portion of the housing and leading to the housing interior, the second opening located at the top of the back portion, proximate the top portion of the housing; and
b) a flue external to the housing and adapted to be coupled to the intermediate assembly below the second opening and in front of the first opening such that the flue encompasses and is in fluid communication with the first and second openings, the flue defining an inlet for conducting air into the flue and an outlet for conducting air out of the flue and into the housing through the first and second openings.

16. The assembly of claim 15, wherein the flue comprises essentially perpendicular members that define a coupling portion, such that when the flue is coupled to the housing the coupling portion fits tightly over and follows the contour of the top back corner of the housing.

17. An assembly for supplying heated air to a housing with an interior that is adapted to hold air conditioning equipment, the housing comprising a top portion and a back portion, where the top portion defines a first opening that leads to the housing interior, the first opening located proximate the back of the top portion, where the back portion defines a second opening that leads to the housing interior, the second opening located proximate the top of the back portion, and where the first opening is contiguous with the second opening, the assembly comprising:
a) an intermediate assembly adapted to be coupled to the support assembly, the intermediate assembly defining at least part of the back portion of the housing and at least part of the top portion of the housing, the intermediate assembly further defining:
i) a first opening extending across substantially all of the width of the top portion of the housing and leading to the housing interior, the first opening located at the back of the top portion, proximate the back portion of the housing; and
ii) a second opening extending across substantially all of the width of the back portion of the housing and leading to the housing interior, the second opening located at the top of the back portion, proximate the top portion of the housing; and
b) a flue external to the housing and adapted to be coupled to the intermediate assembly below the second opening and in front of the first opening, where the flue defines an air passageway encompasses and is in fluid communication with the first and second openings, the air passageway defining an inlet for conducting air into the air passageway and an outlet for conducting air out of the passageway and into the housing through the first and second openings.

18. The assembly of claim 17, wherein the flue comprises essentially perpendicular members that define a coupling portion, such that when the flue is coupled to the housing the coupling portion fits tightly over and follows the contour of the top back corner of the housing.

19. The assembly of claim 17, wherein the flue extends out an angle of no more than about ninety degrees from the back portion of the housing.

20. The assembly of claim 17, wherein the flue extends out from the back portion of the housing, and wherein the flue extends up after extending out from the back portion of the housing.

21. A system for use in a data center, the system comprising:
a plurality of cabinets, each cabinet comprising a generally rectangular vertical front face, two generally rectangular vertical side faces coupled to the front face, a generally rectangular top face coupled to the side faces and to the front face, a generally rectangular back face coupled to the side faces, wherein the plurality of cabinets are arranged in a first row and a second row horizontally displaced from each other such that the front faces of the cabinets in the first row are facing the front faces of the cabinets in the second row to define a cold aisle between the front faces;
where at least one of the cabinets is an equipment cabinet adapted to house one or more heat-generating components, and at least one of the cabinets is an air-conditioning cabinet adapted to house one or more air-cooling components;
a first baffle proximate the front face of a first cabinet in the first row and the front face of a first cabinet in the second row, the first baffle being configured to inhibit horizontal airflow into and out of the cold aisle;
a second baffle proximate the front face of a last cabinet in the first row and the front face of a last cabinet in the second row, the second baffle being configured to inhibit horizontal airflow into and out of the cold aisle;
a chimney in communication with the equipment cabinet, for conducting air warmed by the heat-generating components from the interior of the equipment cabinet to a location above the cabinets; and
a flue in communication with the air-conditioning cabinet, for conducting warmed air from a location above the cabinets to the interior of the air-conditioning cabinet.

22. The system of claim 21, where the chimney defines an air passageway that is in fluid communication with the interior of the equipment cabinet, the air passageway comprising an inlet for taking in air leaving the equipment cabinet and an outlet for conducting the air out of the air passageway to the location above the cabinets.

23. The system of claim 21, where the flue defines an air passageway that is in fluid communication with the interior of the air-conditioning cabinet, the air passageway comprising an inlet for conducting air from the location above the cabinets into the air passageway and an outlet for conducting air out of the air passageway into the air-conditioning cabinet.
